(19) United States
(12) Patent Application Publication
(10) Pub. No.: US 2025/0017009 A1
(43) Pub. Date: Jan. 9, 2025

(54) SEMICONDUCTOR DEVICE AND MANUFACTURING METHOD OF THE SAME, AND ELECTRONIC SYSTEM

(71) Applicant: Samsung Electronics Co., Ltd., Suwon-si (KR)

(72) Inventors: Siyeong Yang, Suwon-si (KR); Yuyeon Kim, Suwon-si (KR); Chaeho Kim, Suwon-si (KR)

(21) Appl. No.: 18/442,229

(22) Filed: Feb. 15, 2024

(30) Foreign Application Priority Data
Jul. 3, 2023 (KR) 10-2023-0085944

(51) Int. Cl. H10B 43/27; H01L 23/00; H01L 25/065; H01L 25/18; H10B 41/27; H10B 80/00

(52) U.S. Cl. CPC H10B 43/27; H01L 24/08; H01L 25/0657; H01L 25/18; H10B 41/27; H10B 80/00; H01L 2224/08145; H01L 2924/1431; H01L 2924/14511

(57) ABSTRACT

A semiconductor device includes a gate stacking structure, a channel structure, and a horizontal conductive layer. The gate stacking structure may include a plurality of gate electrodes and a plurality of insulation layers that are alternately stacked. The channel structure may be provided with an inner portion extending into the gate stacking structure and a protruded portion that protrudes from one surface of the gate stacking structure. The horizontal conductive layer may be connected to the protruded portion of the channel structure. In this case, the channel structure may include a semiconductor layer. The semiconductor layer may include a polycrystalline region in at least the protruded portion and including a polycrystalline semiconductor material and in a channel region positioned in the inner portion and having a crystal structure different from a crystal structure of the polycrystalline region.

### CROSS-REFERENCE TO RELATED APPLICATION

This application claims priority to and the benefit of Korean Patent Application No. 10-2023-0085944 filed on Jul. 3, 2023, in the Korean Intellectual Property Office, the entire content of which is incorporated herein by reference.

### BACKGROUND

### (a) Field

The present disclosure relates to a semiconductor device and a manufacturing method thereof, and an electronic system.

### (b) Description of the Related Art

In an electron system implementing a data storage, a semiconductor device may be capable of storing high-capacity data. Accordingly, research is ongoing into methods for increasing data storage capacity of semiconductor devices. As one method for increasing the data storage capacity of a semiconductor device, a semiconductor device including three-dimensionally arranged memory cells instead of two-dimensionally arranged memory cells has been proposed.

### SUMMARY

Some embodiments may provide a semiconductor device having improved reliability and performance, a manufacturing method thereof, and an electronic system.

A semiconductor device according to an embodiment includes a gate stacking structure, a channel structure, and a horizontal conductive layer. The gate stacking structure may include a plurality of gate electrodes and a plurality of insulation layers that are alternately stacked. The channel structure may be provided with an inner portion extending into the gate stacking structure and a protruded portion that protrudes from one surface of the gate stacking structure. The horizontal conductive layer may be connected to the protruded portion of the channel structure. In this case, the channel structure may include a semiconductor layer. The semiconductor layer may include a polycrystalline region in at least the protruded portion and including a polycrystalline semiconductor material and in a channel region at the inner portion and having a crystal structure that is different from a crystal structure of the polycrystalline region.

An electronic system according to an embodiment includes a main substrate, the above-described semiconductor device on the main substrate, and a controller electrically connected with the semiconductor device on the main substrate.

A manufacturing method of a semiconductor device according to an embodiment includes forming of a stacking structure, forming of a preliminary channel structure, forming of a semiconductor layer, and forming of a plurality of gate electrodes. In the forming of the stacking structure, a stacking structure including a plurality of sacrificial insulation layers and a plurality of insulation layers that are alternately stacked on a substrate may be formed. In the forming of the preliminary channel structure, a penetration portion extending into a stacking structure may be formed, and the preliminary channel structure including a preliminary semiconductor layer including an amorphous semiconductor material may be formed in the penetration portion. In the forming of the semiconductor layer, a heat treatment process may be performed for crystallization of the preliminary semiconductor layer. In this case, a first region of the preliminary semiconductor layer may be crystallized to have a polycrystalline structure, and a second region of the preliminary semiconductor layer may be crystallized to have a single crystal structure or a quasi-single crystal structure. In the forming of the plurality of gate electrodes, the plurality of sacrificial insulation layers may be substituted with the plurality of gate electrodes.

According to an embodiment, damage to or defects in the channel structure may be reduced or prevented by a semiconductor layer including a polycrystalline region having a polycrystalline semiconductor material. In addition, cell current can be increased by the semiconductor layer including a channel region having a crystal structure different from a crystal structure of the polycrystalline region. Accordingly, reliability and performance of a semiconductor device can be improved.

According to an embodiment, a semiconductor device having improved reliability and performance can be formed by a process of reasonable complexity.

### BRIEF DESCRIPTION OF THE DRAWINGS

FIG. 1 is a schematic cross-sectional view a semiconductor device according to some embodiments.

FIG. 2 is an enlarged cross-sectional view of the portion A of FIG. 1.

FIG. 3 is an enlarged cross-sectional view of the portion B of FIG. 2.

FIG. 4 is an enlarged cross-sectional view of a part of the semiconductor device according to a modified embodiment.

FIG. 5A to FIG. 5H are partial cross-sectional views of a semiconductor manufacturing method according to some embodiments.

FIG. 6 schematically illustrates an electronic system including a semiconductor device according to some embodiments.

FIG. 7 schematically illustrates an electronic system including a semiconductor device according to some embodiments.

FIG. 8 is a schematic cross-sectional view of a semiconductor package according to some embodiments.

### DETAILED DESCRIPTION

Embodiments of the present disclosure will be described more fully hereinafter with reference to the accompanying drawings for those skilled in the art to which the present disclosure pertains to easily practice the present disclosure. The present disclosure may be implemented in any of various different forms and is not limited to the embodiment provided herein. The same reference numerals are used for the same components in the drawings, and redundant descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

A portion unrelated to the description is omitted to clearly describe the present disclosure. Further, since sizes and thicknesses of portions, regions, members, units, layers, films, etc. shown in the accompanying drawings may be arbitrarily shown for better understanding and ease of description, the present disclosure is not limited to the illustrated sizes and thicknesses. Thicknesses of some portions, regions, members, units, layers, films, etc. may be enlarged in the drawings to improve clarity. In addition, in the drawings, thicknesses of portions, regions, members, units, layers, films, etc. may be exaggerated for convenience of explanation.

It will be understood that when a component such as a layer, film, region, or substrate is referred to as being “on” another component, it may be directly on other component or intervening components may also be present. In contrast, when a component is referred to as being “directly on” another component, there are no intervening components present. Further, when a component is referred to as being “on” or “above” a reference component, a component may be positioned on, e.g., above, or below the reference component, and may not necessarily be “on” or “above” the reference component toward an opposite direction of gravity.

In addition, unless explicitly described to the contrary, the word “comprise”, “include”, or “contain”, and variations such as “comprises”, “comprising”, “includes”, “including”, “contains” or “containing” will be understood to imply the inclusion of other component rather than the exclusion of any other components.

Further, throughout the specification, a phrase “on a plane”, “in a plane”, “on a plan view”, or “in a plan view” may indicate a case where a portion is viewed from above or a top portion, and a phrase “on a cross-section” or “in a cross-section” may indicate when a cross-section taken along a vertical direction is viewed from a side.

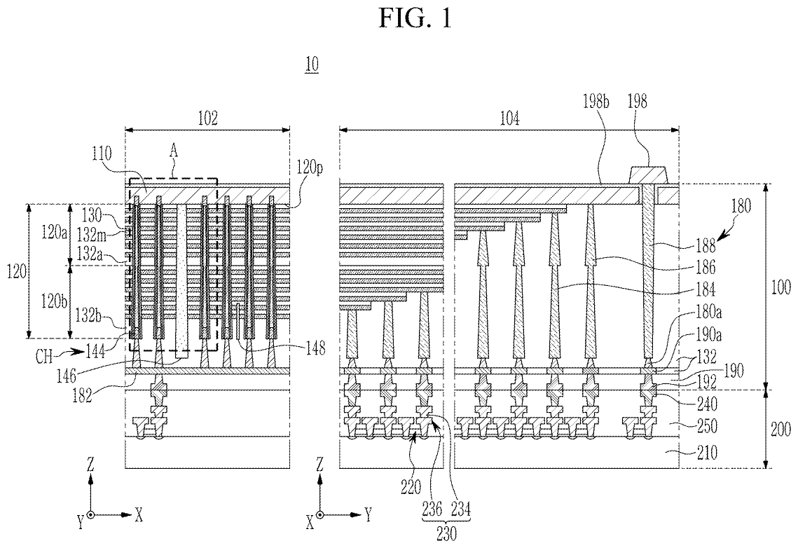

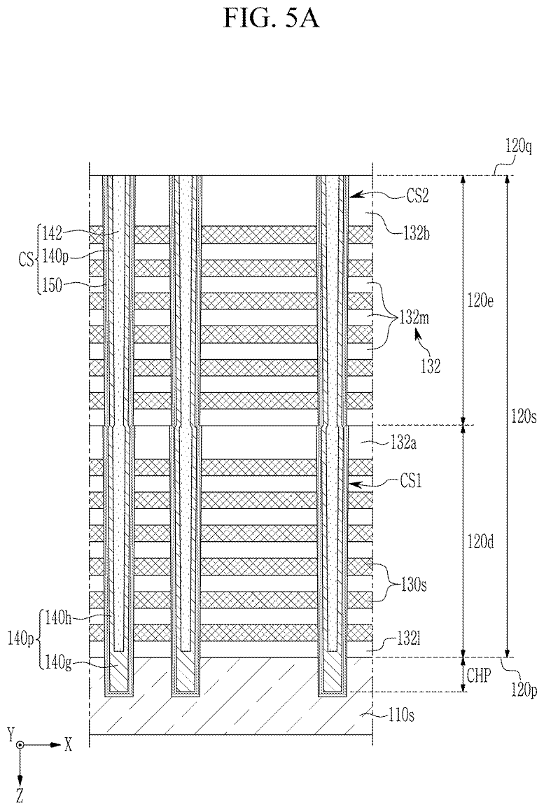

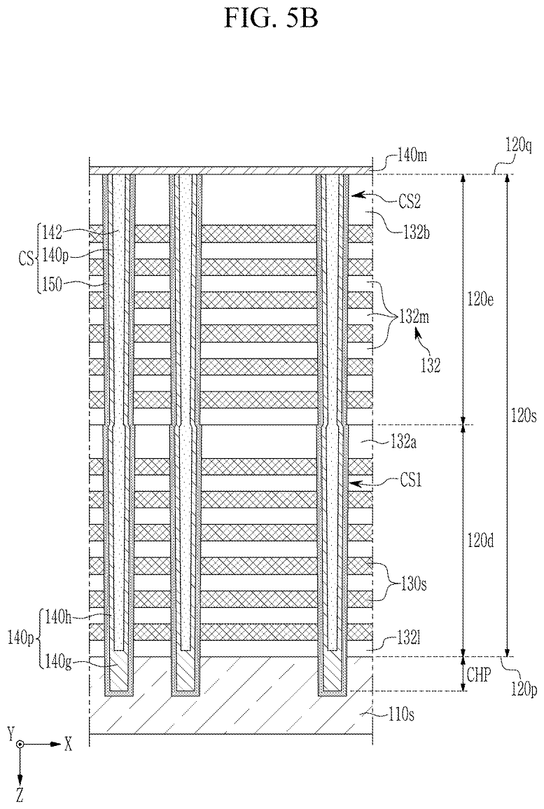

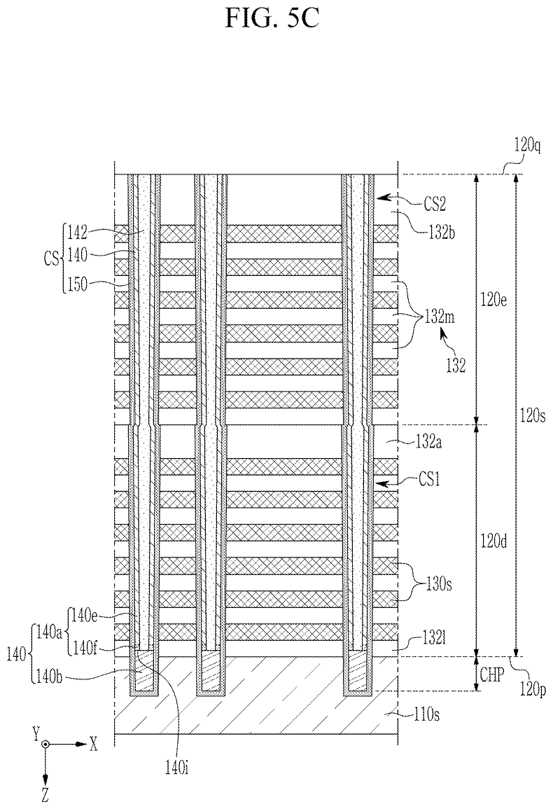

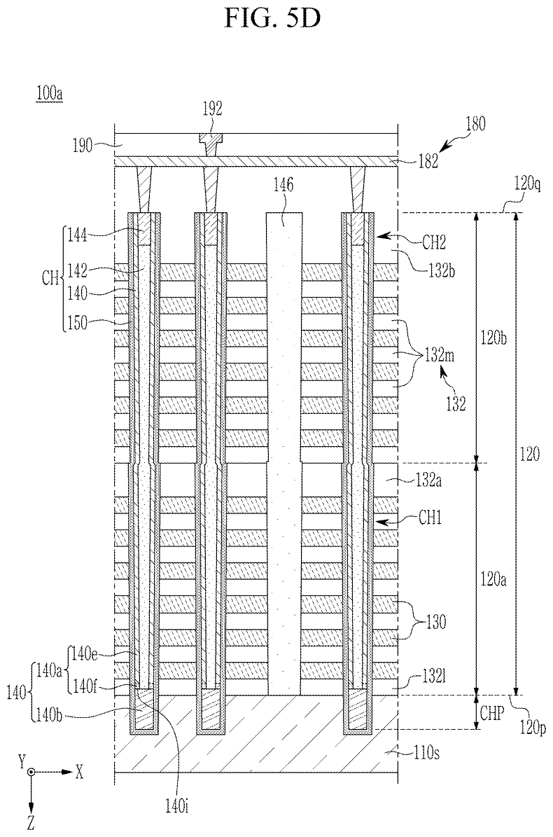

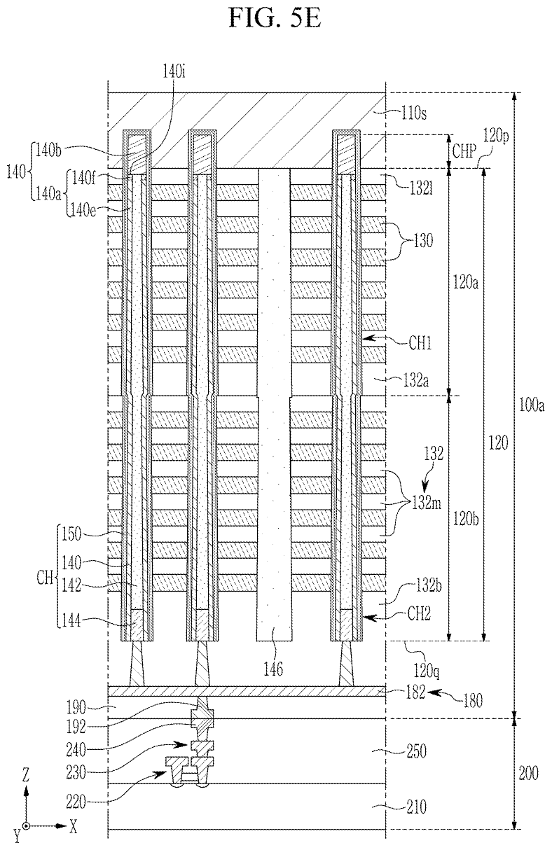

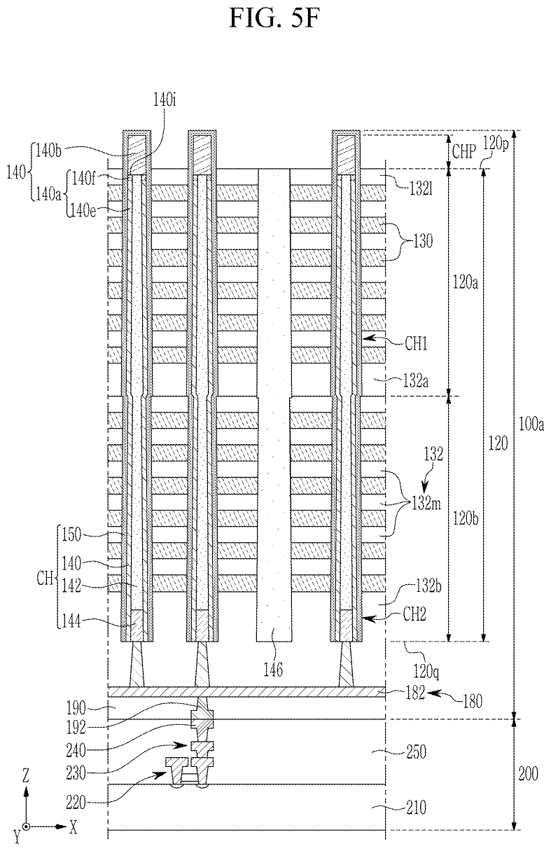

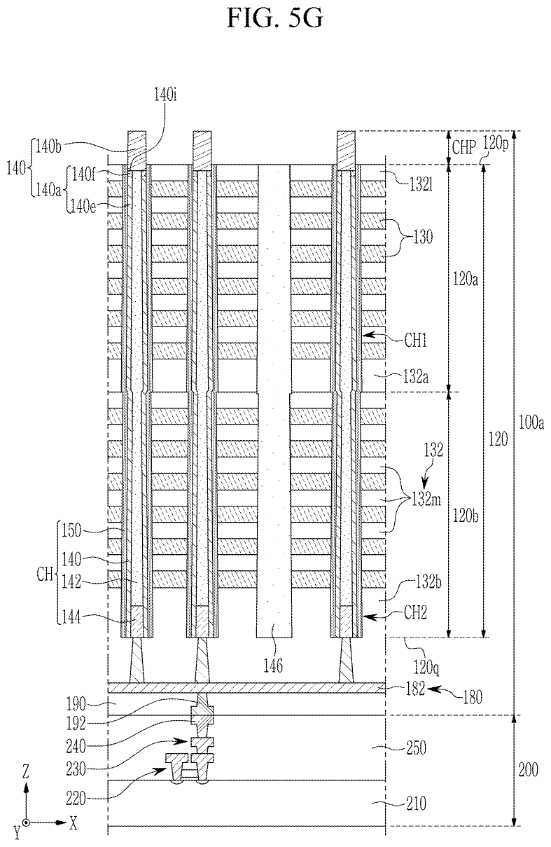

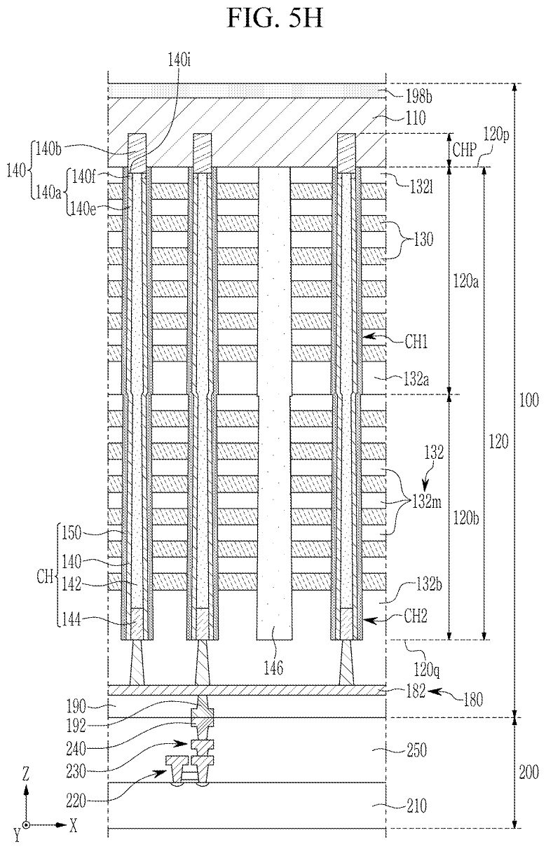

Hereinafter, referring to FIG. 1 to FIG. 4, and FIG. 5A to FIG. 5H, a semiconductor device according to an embodiment and a modified embodiment, and a manufacturing method thereof will be described in detail.

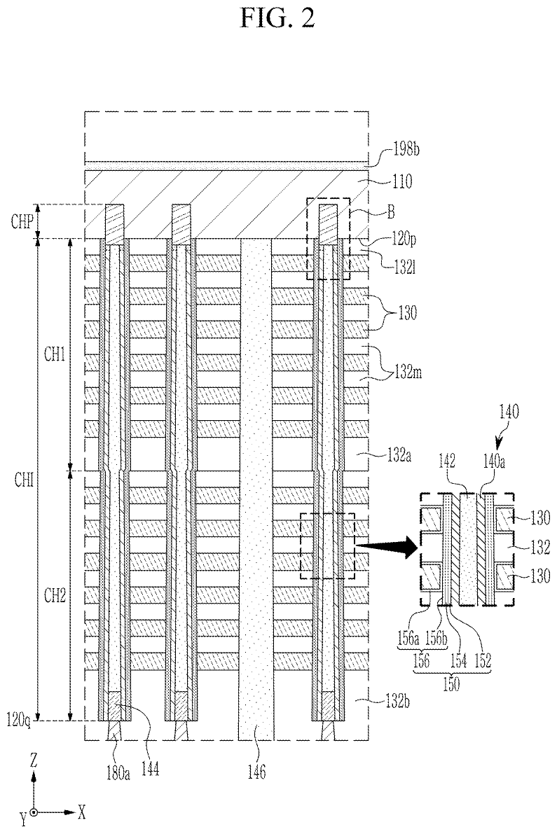

FIG. 1 is a schematic cross-sectional view a semiconductor device according to some embodiments, and FIG. 2 is an enlarged cross-sectional view of the portion A of FIG. 1.

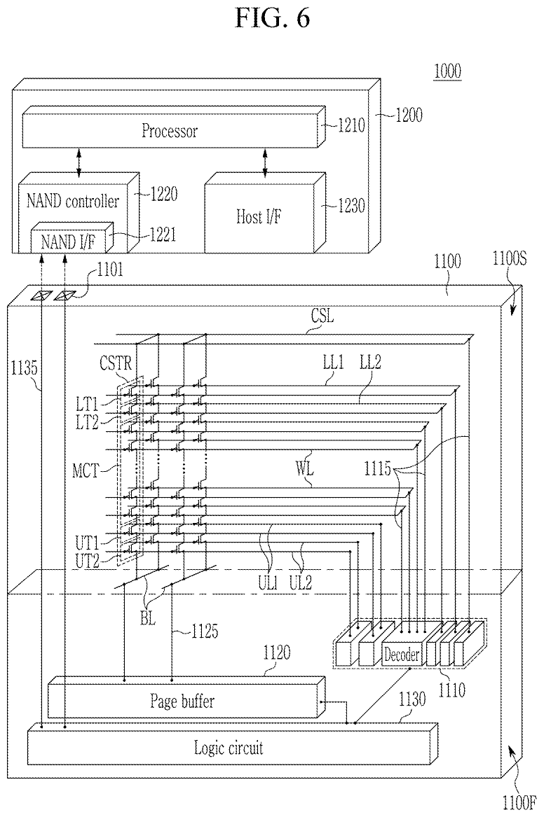

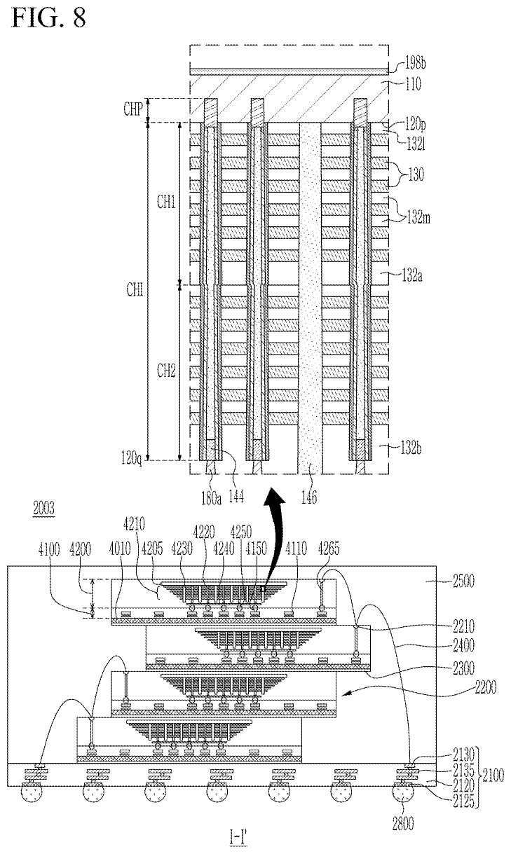

Referring to FIG. 1 and FIG. 2, a semiconductor device 10 according to some embodiments may include a cell region 100 provided with a memory cell structure and a circuit region 200 provided with a peripheral circuit structure that controls the memory cell structure. In this case, the cell region 100 and the circuit region 200 may be a bonded semiconductor device of a chip-to-chip (C2C) structure bonded by a wafer bonding method (e.g., hybrid bonding). For example, the circuit region 200 and the cell region 100 may be respective portions corresponding to a first structure 1100F and a second structure 1100S of a semiconductor device 1100 included in the electronic system 1000 shown in FIG. 6. For example, the circuit region 200 and the cell region 100 may be respective portions including to a first structure 1100F and a second structure 1100S of a semiconductor chip 2200 shown in FIG. 8.

Here, the circuit region 200 may include a peripheral circuit structure on the first substrate 210, and the cell region 100 may include a gate stacking structure 120 and a channel structure CH as a memory cell structure. The circuit region 200 may include a first wiring portion 230 electrically connected to the peripheral circuit structure, and the cell region 100 may include a second wiring portion 180 electrically connected to the memory cell structure.

In an embodiment, the cell region 100 may be disposed on the circuit region 200. Accordingly, the area corresponding to the circuit region 200 needs not to be assured separately from the cell region 100, and thus the area of the semiconductor device 10 can be reduced. However, an embodiment is not limited thereto, and numerous variations are applicable.

The circuit region 200 may include a first substrate 210, a circuit element 220 and a first wiring portion 230 on the first substrate 210, and a first bonding structure 240 on the circuit element 220 and the first wiring portion 230 at a surface opposing the cell region 100. In addition, the circuit region 200 may further include an insulation layer 250 covering the first substrate 210, the circuit element 220, the first wiring portion 230, or the like.

The first substrate 210 may be a semiconductor substrate including a semiconductor material. For example, the first substrate 210 may be a semiconductor substrate formed of a semiconductor material, and may be a semiconductor substrate in which a semiconductor layer is formed on a base substrate. For example, the first substrate 210 may be formed of single crystal silicon or polysilicon, epitaxial silicon, germanium, silicon-germanium, silicon-on-insulator (SOI), and/or germanium-on-insulator (GOI), or the like.

The circuit element 220 on the first substrate 210 may include any of various circuit elements that control operation of the memory cell structure provided in the cell region 100. For example, the circuit element 220 may form a peripheral circuit structure, such as a decoder circuit (refer to 1110 in FIG. 6), a page buffer (refer to 1120 in FIG. 6), a logic circuit (refer to 1130 in FIG. 6), or the like. The circuit element 220 may include, for example, a transistor, but this is not restrictive. For example, the circuit element 220 may include not only an active element, such as a transistor or the like, but also a passive element, such as a capacitor, a resistor, an inductor, or the like.

The first wiring portion 230 disposed on the first substrate 210 may electrically connect the circuit element 220 and the first bonding structure 240. In an embodiment, the first wiring portion 230 may include a plurality of wiring layers 236 spaced apart with a first insulation layer 232 therebetween and connected by a contact via 234 to form a preferred path. The wiring layer 236 or the contact via 234 may include any of various conductive materials, and the first insulation layer 250 may include any of various insulating materials, such as a silicon oxide, a silicon nitride, or the like. The first insulation layer 250 may be formed of one or a plurality of insulation layers.

The cell region 100 may include the cell array region 102 and a connection region 104. A gate stacking structure 120 and a channel structure CH may be disposed on the horizontal conductive layer 110 in the cell array region 102. The connection region 104 may be disposed at the periphery of the cell array region 102. A structure for connecting the gate stacking structure 120 and/or channel structure CH with the circuit region 200 formed in the cell array region 102 or an external circuit may be in the connection region 104.

In this specification, unless otherwise specified, an upper or lower portion may mean an upper or lower portion in a manufacturing process. For example, unless otherwise specified, for the gate stacking structure 120, the channel structure CH, or the like, an upper portion may mean a portion positioned far from the horizontal conductive layer 110 or a portion positioned close to the circuit region 200, and a lower portion may mean a part positioned close to the horizontal conductive layer 110 or a portion positioned far from the circuit region 200. Unless otherwise specified, for the horizontal conductive layer 110, an upper portion may mean a portion positioned far from the circuit region 200 as an upper portion in FIG. 1 and FIG. 2, and a lower portion may mean a portion positioned close to the circuit region 200 as a lower portion in FIG. 1 and FIG. 2.

In an embodiment, the horizontal conductive layer 110 may be formed after removing a semiconductor (refer to 110s in FIG. 5A) disposed on one surface 120p of the gate stacking structure 120. This will be described later in more detail. Here, the one surface 120p of the gate stacking structure 120 may be a bottom surface of the gate stacking structure 120 in a manufacturing process, and or may be an upper surface of the gate stacking structure 120 in FIG. 1 and FIG. 2 in which the horizontal conductive layer 110 is disposed.

The gate stacking structure 120 may be disposed on the horizontal conductive layer 110. The gate stacking structure 120 may include a plurality of cell insulation layers 132 and a plurality of gate electrodes 130 that are alternately stacked.

The cell insulation layer 132 may include an interlayer insulation layer 132m, upper insulation layers 132a and 132b, and a bottom insulation layer 132l. The interlayer insulation layer 132m may be between two adjacent gate electrodes 130 in the gate stacking structure 120. The upper insulation layers 132a and 132b may be on an upper side (the lower portion in FIG. 1) of the gate stacking structure 120. The bottom insulation layer 132l may be between a gate electrode adjacent to the one surface 120p of the gate stacking structure 120 among the plurality of gate electrodes 130 and the horizontal conductive layer 110. The bottom insulation layer 132l may be adjacent to one surface of the gate stacking structure 120 or may form the one surface 120p of the gate stacking structure 120. For simple illustration, in FIG. 1, it is illustrated that the cell insulation layer 132 is provided as being without a boundary in the connection region 104, except for a portion where a connection wire 190a is disposed. However, the cell insulation layer 132 in the connection region 104 may have any of various structures including one or a plurality of insulation layers, and an embodiment is not limited thereto.

The gate electrode 130 may include any of various conductive materials. For example, the gate electrode 130 may include a metal material such as tungsten (W), copper (Cu), aluminum (Al), or the like, polysilicon, a metal nitride (e.g., titanium nitride (TiN), tantalum nitride (TaN), etc.), or a combination thereof. As shown in the enlarged view of FIG. 2, a blocking layer 156 (e.g., a first blocking layer 156a) formed of an insulating material may be disposed at an outer side of the gate electrode 130. The cell insulation layer 132 may include any of various insulating materials. For example, the cell insulation layer 132 may include a silicon oxide, a silicon nitride, a silicon oxynitride, a low dielectric constant material having lower permittivity than a silicon oxide, or a combination thereof.

The channel structure CH that extends into or penetrates the gate stacking structure 120 and extends in a cross-direction that crosses the horizontal conductive layer 110 (e.g., a vertical direction that is perpendicular to the horizontal conductive layer 110) may be formed. The channel structure CH may have a column shape. For example, in a cross-sectional view, the channel structure CH may have an inclined side surface of which a width becomes narrower as it approaches the horizontal conductive layer 110 according to the aspect ratio. However, embodiments are not limited thereto, and the structure and shape of the channel structure CH may be variously modified.

The channel structures CH each form one memory cell string, and a plurality of channel structures CH may be apart from each other while forming rows and columns in a plan view. For example, in a plan view, a plurality of channel structures CH may be disposed to have any of various forms, such as a lattice form and a zigzag form. However, embodiments are not limited thereto, and the disposition and shape of the channel structure CH may be variously modified.

In an embodiment, the channel structure CH may include an inner portion CH1 extending into the gate stacking structure 120, and a protruding portion CHP protruding toward an external side (e. g., protruding toward an upper portion in FIG. 2) of the horizontal conductive layer 110 from the one surface 120p of the gate stacking structure 120.

The horizontal conductive layer 110 may be connected to the protruded portion CHP of the channel structure CH. The horizontal conductive layer 110 may also be referred to as a second substrate, a common source electrode, a common source substrate, a common source line, or the like. The horizontal conductive layer 110 may be formed of a conductive material, for example, a semiconductor layer doped with a p-type or n-type dopant. In an embodiment, the horizontal conductive layer 110 may be formed of a polycrystalline semiconductor material (e.g., polysilicon) doped with a p-type or n-type dopant. A current may flow stably through the horizontal conductive layer 110 doped with a dopant. However, embodiments are not limited thereto, and the horizontal conductive layer 110 may be formed of any of various materials.

As described above, when the horizontal conductive layer 110 includes polysilicon, a grain size of a polycrystalline region 140b having a polycrystalline structure may be smaller than that of the horizontal conductive layer 110. However, embodiments are not limited thereto, and a grain size of a polycrystalline region 140b may be equal to or larger than that of the horizontal conductive layer 110. The polycrystalline region 140b provided in the semiconductor layer 140 included in the channel structure CH will be described in more detail below.

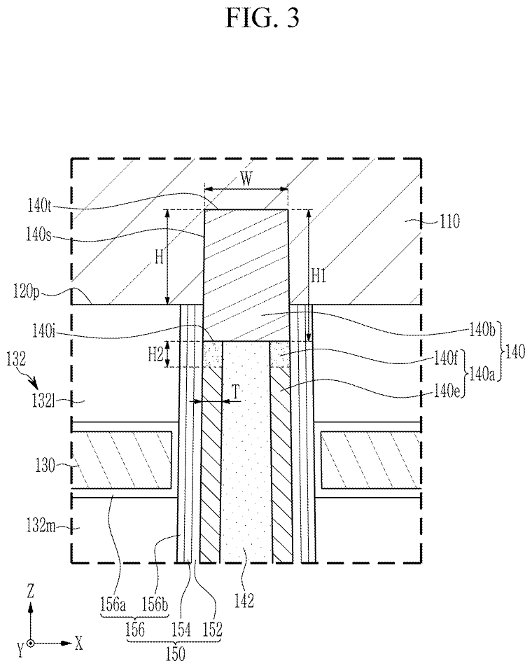

In an embodiment, the horizontal conductive layer 110 may be entirely formed on an outer surface of the protruded portion CHP and may be entirely connected to the outer surface of the protruded portion CHP. In further detail, the horizontal conductive layer 110 is entirely on a bottom surface (refer to 140t of FIG. 3, hereinafter the same) and a side surface (refer to 140s FIG. 3, hereinafter the same) of the semiconductor layer 140 at the protruded portion CHP and thus may be entirely connected to the semiconductor layer 140 at the protruded portion CHP (i.e., the bottom surface 140t and the side surface 140s of the polycrystalline region 140b).

For example, the horizontal conductive layer 110 may have a shape of a substrate that entirely covers the bottom surface 140t and the side surface 140s of the semiconductor 140 (e.g., the polycrystalline region 140b) at the protruded portion CHP. That is, the outer surface of the horizontal conductive layer 110 may be positioned on the same plane as a whole or formed of a flat surface. The sum of a height (refer to H in FIG. 3) of the protruded portion CHP and a height of the horizontal conductive layer 110 at the protruded portion CHP, and a thickness of the horizontal conductive layer 110 in a portion where the protruded portion CHP is not provided) may be entirely uniform. However, embodiments are not limited thereto. The outer surface of the horizontal conductive layer 110 may have a curve according to the shape of the protruded portion CHP, or the horizontal conductive layer 110 may have any of various other shapes.

In an embodiment, electrical properties can be improved by increasing a connection area between the protruded portion CHP of the channel structure CH and the horizontal conductive layer 110. In addition, it is possible to connect the protruded portion CHP of the channel structure CH and the horizontal conductive layer 110 through a process of reasonable complexity.

The channel structure CH may include a semiconductor layer 140 and a gate dielectric layer 150 positioned on the semiconductor layer 140 between the gate electrode 130 and the semiconductor layer 140. In addition, the channel structure CH may further include a core insulation layer 142 and a channel pad 144.

The gate dielectric layer 150 may include a tunneling layer 152, a charge storage layer 154, and a blocking layer 156 sequentially formed on the semiconductor layer 140. The tunneling layer 152 may include an insulating material capable of charge tunneling. For example, the tunneling layer 152 may include a silicon oxide or a silicon oxynitride. The charge storage layer 154 is used as a data storage region and may include polysilicon, a silicon nitride, or the like. The blocking layer 156 may include an insulating material that can reduce or prevent an undesirable charge inflow into the gate electrode 130. For example, the blocking layer 156 may include a silicon oxide, a silicon nitride, a silicon oxynitride, a high dielectric constant material having higher permittivity than a silicon oxide, or a combination thereof. In an embodiment, the blocking layer 156 may include a first blocking layer 156a including a portion extending in parallel with the gate electrode 130 and a second blocking layer 156b perpendicularly extending between the first blocking layer 156a and the charge storage layer 154. However, the material and stacking structure of the gate dielectric layer 150 may be variously modified, and embodiments are not limited thereto.

The core insulation layer 142 may be inside the semiconductor layer 140. For example, the core insulation layer 142 may be in a central area inside a channel region (140a in FIG. 3, hereinafter the same) at an inner portion CH1 of the channel structure CH. Thus, by reducing a thickness of the channel region 140a of the semiconductor layer 140, the size of the electric field applied to the channel region 140a may be reduced, thereby inhibiting or preventing electric fields from adjacent ones of the plurality of gate electrodes 130 from interfering with each other.

The core insulation layer 142 may include any of various insulating materials. For example, the core insulation layer 142 may include a silicon oxide, a silicon nitride, a silicon oxynitride, or a combination thereof. However, the material of the core insulation layer 142 can be variously modified, and embodiments are not limited thereto.

The semiconductor layer 140 may mean a layer including a semiconductor material. At least a portion of the semiconductor layer 140 may be formed of a semiconductor material layer that singly includes the semiconductor material. A part of the semiconductor layer 140 may include a portion including a semiconductor material and another material (e.g., the interface portion 140f).

In an embodiment, the semiconductor layer 140 may include a polycrystalline region 140b and a channel region 140a each having a different crystal structure. Referring to FIG. 3, together with FIG. 1 and FIG. 2, the semiconductor layer 140 will be described in more detail.

FIG. 3 is an enlarged cross-sectional view of the portion B of FIG. 2.

Referring to FIG. 1 to FIG. 3, in an embodiment, the semiconductor layer 140 may include the polycrystalline region 140b at least partially filling at least the protruded portion CHP and at least a portion of the inner portion CH1 and including a polycrystalline semiconductor material. The channel region 140a in the inner portion CH1 may have a crystal structure that is different from that of the polycrystalline region 140b. In some embodiments, the channel region 140a may have a single crystal structure or a quasi-single crystal structure.

Here, the polycrystalline structure may mean a crystal structure having a grain boundary including a plurality of crystal grains having different crystal directions. For example, the polycrystalline region 140b may have a plurality of randomly crystallized crystal grains. For example, the polycrystalline region 140b may have a polycrystalline structure by solid-state crystallization.

Here, the single crystal structure may mean a crystal structure having one crystal direction and having no grain boundaries. A quasi-single crystal structure may mean a crystal structure determined to have one crystal direction as a whole, but atoms are missing or defects, such as twin boundaries, are located in a limited area locally. The quasi-single crystal structure may be referred to as a similar single crystal structure, a quasi-single crystal structure, or the like. For example, the channel region 140a may have a single crystal or quasi-single crystal structure by metal-induced crystallization.

In an embodiment, the polycrystalline region 140b and the channel region 140a may be formed by performing a crystallization process after forming a preliminary semiconductor layer (refer to 140p in FIG. 5A, hereinafter the same) including a first region (refer to 140g in FIG. 5A, hereinafter the same) and a second region (refer to 140h in FIG. 5A, hereinafter the same). In the crystallization process, the second region 140h is crystalized by a metal induced crystallization (MIC) process, for example, a metal induced lateral crystallization (MILC) process, such that the channel region 140a having a single crystal structure or a quasi-single crystal structure is formed. In the crystallization process, the first region 140g is crystalized by a solid phase crystallization (SPC) process, such that the polycrystalline region 140b having the polycrystalline structure is formed.

In an embodiment, the first region 140g or the polycrystalline region 140b may have a shape or size facilitating solid-phase crystallization, and the second region 140h or the channel region 140a may have a shape or size facilitating metal-induced crystallization. In this way, by forming the first region 140g and the second region 140h in different shapes or sizes, the first region 140g and the second region 140h are crystallized in different ways in the crystallization process to form the polycrystalline region 140b and the channel region 140a having different shapes and different crystal structures.

In an embodiment, the first region 140g may have a shape substantially the same as that of the polycrystalline region 140b, and the second region 140h may have a shape substantially the same as the channel region 140a. Hereinafter, description of the shape or size of the polycrystalline region 140b may be applied to the first region 140g, and description of the shape or size of the channel region 140a may be applied to the second region 140h.

In an embodiment, the polycrystalline region 140b may at least partially fill at least the protruded portion CHP, and may be additionally in a part of the inner portion CH1. When viewed from an extension direction of the channel structure CH (Z-axis direction of the drawing), the channel region 140a may be positioned on an entire portion or a part of the inner portion CH1. That is, in the extension direction of the channel structure CH, the channel region 140a may be positioned in a portion other than the portion where the polycrystalline region 140b and/or the channel pad 144 are positioned in the channel structure CH.

For example, the polycrystalline region 140b may at least partially fill the protruded portion CHP and might not be in the inner portion CH1. In this case, in the extension direction of the channel structure CH, the channel region 140a may be entirely positioned on the inner portion CH1 or entirely positioned on the inner portion CH1 except for the channel pad 144. As another example, the polycrystalline region 140b may be in a part of the inner portion CH1 together with the protruded portion CHP. In this case, in the extension direction of the channel structure CH, the channel region 140a may be partially positioned in the inner portion CH1 except for a portion where the polycrystalline region 140b and/or channel pad 144 are positioned.

A boundary portion 140i between the polycrystalline region 140b and the channel region 140a may be on the same plane as the one surface 120p of the gate stacking structure 120 or may be at an inside of the gate stacking structure 120. A height H1 of the polycrystalline region 140b in the extension direction (Z-axis direction of the drawing) of the channel structure CH may be equal to or greater than a height H of the protruded portion CHP. In this case, the boundary portion 140i between the polycrystalline region 140b and the channel region 140a may be positioned at a portion where the bottom insulation layer 132l is positioned. That is, the boundary portion 140i may be on the same plane as at least one of one surface and the other surface of the bottom insulation layer 132l, or may be between one surface and the other surface of the bottom insulation layer 132l.

For example, the boundary portion 140i between the polycrystalline region 140b and the channel region 140a may be at an inside of the gate stacking structure 120, and the height H1 of the polycrystalline region 140b may be greater than the height H of the protruded portion CHP. That is, the boundary portion 140i may be between one surface and the other surface of the bottom insulation layer 132l. Then, the polycrystalline region 140b may at least partially fill the protruded portion CHP.

In this case, the bottom surface of the gate dielectric layer 150 may be disposed on the same plane as the one surface 120p of the gate stacking structure 120. This is because the gate dielectric layer 150 is removed based on the one surface 120p of the gate stacking structure 120 in the manufacturing process. However, embodiments are not limited thereto. The bottom surface of the gate dielectric layer 150 may be disposed higher or lower than the one surface 120p of the gate stacking structure 120. For example, when the boundary portion 140i is on the same plane as the one surface 120p of the gate stacking structure 120, the bottom surface of the gate dielectric layer 150 and the boundary portion 140i may be on the same plane (one surface 120p of the gate stacking structure 120). As another example, when the boundary portion 140i is at the inside of the gate stacking structure 120, the boundary portion 140i may be at the inside of the gate stacking structure 120 rather than on the same plane as the bottom surface of the gate dielectric layer 150.

In an embodiment, the polycrystalline region 140b may at least partially fill the protruded portion CHP, and the channel region 140a may be formed to form a part of an inner space of the gate dielectric layer 150 in the inner portion CH1.

In this case, when the polycrystalline region 140b entirely fills the protruded portion CHP without any empty space or gap, it may be regarded that the polycrystalline region 140b may fill the protruded portion CHP. When the polycrystalline region 140b is entirely on an outer surface of the protruded portion CHP and on the boundary portion 140i, it may be regarded that the polycrystalline region 140b may fill the protruded portion CHP. That is, when the polycrystalline region 140b is entirely on the bottom surface 140t and the side surface 140s of the protruded portion CHP and completely fills the inner portion of the gate dielectric layer 150 at the boundary portion 140i in a plan view, it may be regarded that the polycrystalline region 140b may fill the protruded portion CHP.

When the polycrystalline region 140b is entirely positioned at a portion where the boundary portion 140i is positioned without the core insulation layer 142 therein in a plan view, it may be regarded that the polycrystalline region 140b may fill the protruded portion CHP.

Accordingly, at least a part of the polycrystalline region 140b may include an entirely filled portion without an empty space or the core insulation layer 142 therein in a plan view. For example, the polycrystalline region 140b may have a stopper shape, a plug shape, or a truncated circular cone shape in an end portion of the channel structure CH or the protruded portion CHP. In this case, a lower surface (i.e., the bottom surface 140t) of the polycrystalline region 140b may have a smaller size than an upper surface of the polycrystalline region 140b, and the side surface 140s of polycrystalline region 140b may have or include an inclined side surface. However, embodiments are not limited thereto, and the shape of the polycrystalline region 140b may be any of a variety of shapes.

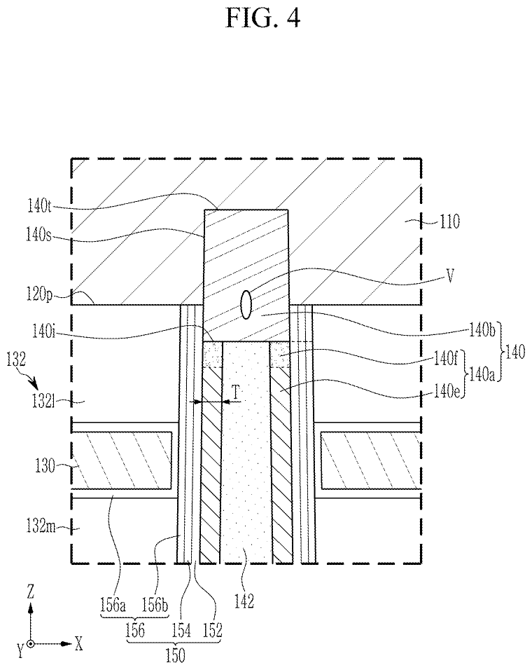

For example, as shown in FIG. 3, the polycrystalline region 140b may be formed while entirely filling a least the protruded portion CHP. As a modified embodiment, as shown in FIG. 4, a void V may be at an inside of the polycrystalline region 140b. Even in this case, the polycrystalline region 140b is entirely formed on the outer surface of the protruded portion CHP and the boundary portion 140i and the core insulation layer 142 is not provided therein. Accordingly, the polycrystalline region 140b may fill the protruded portion CHP. For example, the void V may have a shape that extends in the extension direction (Z-axis direction of the drawing) of the channel structure CH at a central region of the channel structure CH. Such a shape may be formed according to the manufacturing process. For example, the void V remains at a portion where inner surfaces of the preliminary semiconductor layer 140p formed on a side surface of a penetration portion provided for forming the channel structure CH does not completely contact such that the void V has the above shape. However, embodiments are not limited thereto, and the shape, position, or the like of the void V may be variously modified.

Referring back to FIG. 1 to FIG. 3, the core insulation layer 142 may be inside the channel region 140a on the polycrystalline region 140b. Accordingly, the channel region 140a may have a layered shape bordering or surrounding an outer surface of the core insulation layer 142 on the gate dielectric layer 150 formed on the side surface of the channel structure CH. When viewed in a plan view, the channel region 140a may be partially in an inner portion of the gate dielectric layer 150, and an empty space (a space where the core insulation layer 142 is positioned) may be in the central region. For example, when the channel region 140a is viewed in a plan view, the channel region 140a may have a ring shape or an annular shape, and may have a shape that extends longitudinally in an extension direction (Z-axis direction of the drawing) of the channel structure CH. For example, the core insulation layer 142 has a cylinder shape or a truncated circular cone shape, and the channel region 140a may have a shape extending along an outer surface of the core insulation layer 142 in the direction (Z-axis direction of the drawing) of the channel structure CH. However, embodiments are not limited thereto, and the channel region 140a may have any of various shapes.

In this case, the bottom surface of the core insulation layer 142 may be disposed on the same plane as the boundary portion 140i. This is because the core insulation layer 142 is inside the channel region 140a and the core insulation layer 142 is not inside the polycrystalline region 140b. For example, the bottom surface of the core insulation layer 142 may be disposed on the same plane as the bottom surface of the gate dielectric layer 150 or may be at the inside of the gate stacking structure 120. For example, when the boundary portion 140i is on the same plane as one surface 120p of the gate stacking structure 120, the bottom surface of the gate dielectric layer 150 and the bottom surface of the core insulation layer 142 may be on the same plane (one surface 120p of the gate stacking structure 120). As another example, when the boundary portion 140i is at the inside of the gate stacking structure 120, the bottom surface of the core insulation layer 142 may be at the inside of the gate stacking structure 120 rather than the bottom surface of the gate dielectric layer 150.

In an embodiment, the preliminary semiconductor layer 140p for forming the semiconductor layer 140 may be formed to have a layer-like shape by deposition or the like. In this case, the inner surfaces of the preliminary semiconductor layer 140p on the bottom surface 140t or the side surface 140s of the protruded portion CHP at a position where the protruded portion CHP is positioned may be in contact with each other to form the first region 140g in the protruded portion CHP. The layered shape of the second region 140h, except for the first region 140g, may remain as it is. Accordingly, the first region 140g or the polycrystalline region 140b may have a relatively large thickness, size, or volume to have a polycrystalline structure by solid-phase crystallization. The second region 140h or the channel region 140a may have a relatively small thickness, size, or volume to have a single crystal or quasi-single crystal structure by metal-induced crystallization.

As described above, when viewed in a plan view, the polycrystalline region 140b may entirely form the channel structure CH without the core insulation layer 142 at the protruded portion CHP. For example, in the protruded portion CHP, the polycrystalline region 140b may form the protruded portion CHP without the gate dielectric layer 150. In the inner portion CH1, the polycrystalline region 140b may entirely fill an inner space of the gate dielectric layer 150. The channel region 140a may be disposed together with the core insulation layer 142 in the inner space of the gate dielectric layer 150 when viewed in a plan view. That is, when viewed in a plan view, the channel region 140a may be partially formed in the inner space of the gate dielectric layer 150. Accordingly, the polycrystalline region 140b may have a relatively large size and the channel region 140a may have a relatively small size.

A thickness T of the channel region 140a in a direction crossing a side surface of the channel structure CH (e.g., a direction perpendicular to the side surface of the channel structure CH) may be smaller than a height H1 of the polycrystalline region 140b in an extension direction (Z-axis direction of the drawing) of the channel structure CH. Here, the thickness T of the channel region 140a may mean the greatest thickness among thicknesses of the channel region 140a. A diameter or a width W of the polycrystalline region 140b in the bottom surface 140t may mean the smallest diameter or width among diameters or widths that pass a center of the bottom surface 140t in a direction (e.g., one direction in the XY plane of the drawing) crossing the extension direction of the channel structure CH. The height H1 of the polycrystalline region 140b may mean the smallest distance among distances between one surface and the other surface of the polycrystalline region 140b.

For example, a ratio of the diameter or the width W of the bottom surface 140t of the polycrystalline region 140b or the protruded portion CHP to the thickness T of the channel region 140a may be two or less. In this range, the polycrystalline region 140b may be disposed to at least partially fill the protruded portion CHP. For example, the diameter or the width W of the bottom surface 140t of the polycrystalline region 140b or the protruded portion CHP may have the smallest value among the diameters or widths of the channel structure CH. However, embodiments are not limited thereto. Therefore, the ratio of the diameter or the width W of the bottom surface 140t of the polycrystalline region 140b or the protruded portion CHP to the thickness T of the channel region 140a may be greater than two. In some embodiments, a portion having a smaller diameter or width than the diameter or the width W of the bottom surface 140t of the polycrystalline region 140b or the protruded portion CHP may be provided in the channel structure CH.

The height H1 of the polycrystalline region 140b in the extension direction of the channel structure CH may be greater than the thickness T of the channel region 140a. In further detail, a ratio of the height H1 of the polycrystalline region 140b to the thickness T of the channel region 140a may be two or more. This is because the inner surfaces of the preliminary semiconductor layer 140p at least partially fills the protruded portion CHP while contacting each other. In the above range, the height H1 of the polycrystalline region 140b has a sufficient size to at least partially fill the protruded portion CHP. For example, the ratio of the height H1 of the polycrystalline region 140b to the thickness T of the channel region 140a may be two to ten. In the above range, the height H1 of the polycrystalline region 140b may have an appropriate height considering the height H of the protruded portion CHP. However, embodiments are not limited thereto, and the above ratio may have any of various values.

The height H1 of the polycrystalline region 140b may be equal to or larger than the diameter or the width W of the bottom surface 140t of the polycrystalline region 140b or the protruded portion CHP. For example, the ratio of the height H1 of the polycrystalline region 140b to the diameter or the width W of the bottom surface 140t of the polycrystalline region 140b or the protruded portion CHP may be 1.5 or more. This is because the inner surfaces of the preliminary semiconductor layer 140p contact each other to at least partially fill the protruded portion CHP. In the above range, the height H1 of the polycrystalline region 140b has a sufficient size to at least partially fill the protruded portion CHP. For example, the ratio of the height H1 of the polycrystalline region 140b to the diameter or the width W of the bottom surface 140t of the polycrystalline region 140b or the protruded portion CHP may be 1.5 to 3. In the above range, the height H1 of the polycrystalline region 140b may have an appropriate height considering the height H of the protruded portion CHP. However, embodiments are not limited thereto, and the above ratio may have any of various values.

In an embodiment, the channel region 140a may include a channel portion 140e and an interface portion 140f disposed between the channel portion 140w and the polycrystalline region 140b. The channel portion 140e of the channel region 140a may be disposed at a portion where the plurality of gate electrodes 130 are disposed when viewed in the extension direction (Z-axis direction of the drawing) of the channel structure CH. The interface portion 140f of the channel region 140a may be disposed between the channel portion 140e and the polycrystalline region 140b, and the interface portion 140f of the channel region 140a may be at a portion where the plurality of gate electrodes 130 are not disposed when viewed in the extension direction of the channel structure CH. For example, the interface portion 140f of the channel region 140a may be adjacent to one surface 120p of the gate stacking structure 120, and the interface portion 140f may be between an adjacent gate electrode of a plurality of gate electrodes 130 adjacent to one surface 120p of the gate stacking structure 120 and the horizontal conductive layer 110 when viewed from the extension direction of the channel structure CH. For example, when viewed from the extension direction of the channel structure CH, the interface portion 140f may be at a portion where the bottom insulation layer 132l among the cell insulation layer 132 forming one surface 120p of the gate stacking structure 120 is disposed.

In this case, the channel portion 140e and the interface portion 140f may have the same crystal structure (e.g., single crystal structure or quasi-single crystal structure) but may include different materials. For example, the interface portion 140f may include a metal, and the polycrystalline region 140b or the channel portion 140e might not include a metal or may include a metal in a lower content than the interface portion 140f. In this case, the metal included in the interface portion 140f may be a crystallization-inducing metal used in a metal-induced crystallization process.

Because the channel portion 140e is at a portion where the gate electrode 130 is disposed and is directly related to operation of the memory cell, the channel portion 140e may include no metal or have a very low metal content in consideration of the performance of the memory cell. For this purpose, process conditions may be adjusted in the metal-induced crystallization process such that the crystallization-inducing metal does not remain or remains at a low content in the channel portion 140e. In some embodiments, a process of removing the crystallization-inducing metal remaining in the channel portion 140e or reducing the content of the crystallization-inducing metal remaining in the channel portion 140e may be additionally performed before or after the metal-inducing crystallization process. For example, the channel portion 140e might not include a crystallization-inducing metal.

In an embodiment, the crystallization-inducing metal may be provided from one surface 120p of the gate stacking structure 120 and the other surface 120q of the gate stacking structure 120, which is opposite to the one surface 120p. That is, the crystallization-inducing metal is provided from the other surface 120q and moves toward one surface 120p of the gate stacking structure 120 through the channel portion 140e, but cannot easily move to the polycrystalline region 140b. This is because the polycrystalline region 140b has a crystalline structure (e.g., a polycrystalline structure), which makes it difficult for the crystallization-inducing metal to migrate to the polycrystalline region 140b.

Accordingly, the crystallization-inducing metal may remain between the polycrystalline region 140b and the channel portion 140e, and the interface portion 140f of a metal-semiconductor compound including metal (e.g., crystallization-inducing metal) and a semiconductor material included in the channel region 140a may be formed in the corresponding portion. For example, the interface portion 140f may directly contact the polycrystalline region 140b.

In an embodiment, a height H2 of the interface portion 140f may be smaller than the height H1 of the polycrystalline region 140b in the extension direction of the channel structure CH. This is because the interface portion 140f is a portion formed by the remaining crystallization-inducing metal and may have a relatively small thickness H2. For example, the height H2 of the interface portion 140f in the extension direction of the channel structure CH may be 10 nm to 30 nm. However, embodiments are not limited thereto, and the height H2 of the interface portion 140f may have a different value.

In an embodiment, the channel portion 140e, the interface portion 140f, and the polycrystalline region 140b may commonly include the same semiconductor material. This is because the channel portion 140e, the interface portion 140f, and the polycrystalline region 140b are formed from the same preliminary semiconductor layer 140p. In this case, the channel portion 140e and the polycrystalline region 140b may be formed of the same semiconductor material. For example, the channel portion 140e and the polycrystalline region 140b may be formed of a semiconductor material (e.g., silicon). This is because the channel region 140a and the polycrystalline region 140b having different crystal structures are formed without substantial material change from the preliminary semiconductor layer 140p that is formed of a semiconductor material (e.g., silicon). The interface portion 140f has the same crystal structure as the channel portion 140e, but is formed of a metal-semiconductor compound in which the semiconductor material provided in the channel region 140a and the crystallization-inducing metal are combined, which is a material different from that of the channel portion 140e and/or polycrystalline region 140b.

For example, the channel portion 140e may include single crystal or quasi-single crystal silicon, the interface portion 140f may include single crystal or quasi-single crystal metal silicide, and the polycrystalline region 140b may include polysilicon.

In an embodiment, the crystallization-inducing metal may include nickel (Ni), cobalt (Co), palladium (Pd), and/or copper (Cu), or the like. The interface portion 140f may be formed of nickel silicide (e.g., NiSi₂), cobalt silicide, palladium silicide, copper silicide, or the like. However, embodiments are not limited thereto, and the crystallization-inducing metal and/or the material of the interface portion 140f may be variously changed.

As described, the polycrystalline region 140b including a polycrystalline semiconductor material and not including the crystallization-inducing metal may be at a bottom portion of the channel structure CH or the protruded portion CHP without the gate dielectric layer 150. In this case, the polycrystalline region 140b is not substantially etched when the gate dielectric layer 150 is etched such that the polycrystalline region 140b may be a kind of etching stop layer. The polycrystalline region 140b may also be referred to as an etching stop region, a stopper region, or the like. That is, a portion provided with the metal-semiconductor compound (e.g., the interface portion 140f) is not directly exposed to the outside by the polycrystalline region 140b. Accordingly, defects that may occur when the metal-semiconductor compound is exposed to the protruded portion CHP can be prevented.

For reference, conventionally, since a polycrystalline region containing a polycrystalline semiconductor material is not provided in the protruded portion of the channel structure, a portion containing a metal-semiconductor compound may be at a bottom surface of the protruded portion. In the process of removing the gate dielectric layer on the protruded portion, the metal-semiconductor compound exposed to the outside may be removed together. As a result, the core insulation layer is also exposed to the outside and may be removed together. Accordingly, in the process of forming the horizontal conductive layer, a material forming the horizontal conductive layer may be disposed in a portion where the core insulation layer is removed. When such damage or defect of the core insulation layer occurs, the performance of the semiconductor device may deteriorate. In the embodiment, the above problem can be fundamentally mitigated or prevented by disposing the interface portion 140f including the metal-semiconductor compound at the inside of the gate stacking structure 120.

In addition, when the channel region 140a in the inner portion CH1 where the plurality of gate electrodes 130 are disposed has a single crystal structure or a quasi-single crystal structure, electrical resistance of the channel region 140a may be reduced. As a result, a cell current can be increased, and performance of the semiconductor device 10 can be improved. In particular, when the number of gate electrodes 130 increases, the cell current can be effectively improved.

In FIG. 3, it is illustrated that the boundary portion 140i of the channel region 140a and the polycrystalline region 140b, and the boundary between the channel portion 140e and the interface portion 140f are clear. However, embodiments are not limited thereto. Accordingly, the boundary portion 140i of the channel region 140a and the polycrystalline region 140b, and the boundary between the channel portion 140e and the interface portion 140f might not be clearly divided. Even in this case, the polycrystalline region 140b having a polycrystalline semiconductor material may be distinguished from the channel region 140a, and the channel portion 140e and the interface portion 140f having different materials may be distinguished from each other.

In addition, in the above description and FIG. 3, a case that a boundary between the first region 140g and the second region 140h forms the boundary portion 140i between the polycrystalline region 140b and the channel region 140a is illustrated by way of example. That is, a portion having a stopper shape, a plug shape, or a truncated circular cone shape forms the polycrystalline region 140b including a semiconductor material, and a portion having a layered shape may form the channel region 140a having a single crystal or quasi-single crystal structure.

However, embodiments are not limited thereto. For example, the boundary portion 140i between the polycrystalline region 140b and the channel region 140a may be at a different position from a boundary between the first region 140g and the second region 140h. In this case, the polycrystalline region 140b including a semiconductor material may partially include a portion having a layered shape, and the channel region 140a having a single crystal or quasi-single crystal structure may partially include a portion having a stopper shape, a plug shape, or a truncated circular cone shape.

For example, a channel pad 144 connected to the semiconductor layer 140 at an upper portion of the channel structure CH may be on the core insulation layer 142 and may be connected to the semiconductor layer 140. The channel pad 144 may be formed of a conductive material, for example, a semiconductor layer doped with a p-type or n-type dopant. In an embodiment, the channel pad 144 may be formed of a polycrystalline semiconductor material (e.g., polysilicon) doped with a p-type or n-type dopant. A current may flow through the dopant-doped channel pad 144. However, embodiments are not limited thereto, and the horizontal conductive layer 110 may be formed of any of various materials.

As described above, when the channel pad 144 includes polysilicon, a crystal grain size of the polycrystalline region 140b may be smaller than a crystal grain size of the channel pad 144. However, embodiments are not limited thereto, and the crystal grain size of the polycrystalline region 140b may be equal to or greater than the crystal grain size of the channel pad 144.

In an embodiment, the gate stacking structure 120 may include a plurality of gate stacking structures 120a and 120b sequentially stacked on the horizontal conductive layer 110, and the channel structure CH may include a plurality of channel structures CH1 and CH2 that extend into or penetrate the plurality of gate stacking structures 120a and 120b. Then, because the number of stacked gate electrodes 130 may be increased, the number of memory cells may be increased in a stable structure. In the drawing, two gate stacking structures 120 are illustrated, but the embodiments are not limited thereto. Accordingly, the gate stacking structure 120 may be formed of one gate stacking structure or may include three or more gate stacking structures.

The plurality of channel structures CH1 and CH2 forming one channel structure CH may have a form in which they are connected to each other. Each of the plurality of channel structures CH1 and CH2 may have an inclined side surface of which a width becomes narrower closer to the horizontal conductive layer 110 according to an aspect ratio on a cross-section. In addition, as shown in FIG. 2, a bent portion may be provided due to a difference in width in a portion where the first channel structure CH1 and the second channel structure CH2 are connected. As another example, the plurality of channel structures CH1 and CH2 may have inclined side surfaces continuously connected without having a bent portion.

In FIG. 2, it is illustrated by way of example that the gate dielectric layer 150, the semiconductor layer 140 (e.g., channel region 140a), and the core insulation layer 142 of the plurality of channel structures CH1 and CH2 extend to each other thereby forming an integral structure. However, the embodiments are not limited thereto, and the gate dielectric layer 150, the semiconductor layer 140, and the core insulation layer 142 of the plurality of channel structures CH1 and CH2 may be formed separately from each other and may be electrically connected to each other. In addition, a separate channel pad may be additionally provided at a connection portion of the plurality of channel structures CH1 and CH2. As such, the embodiments are not limited to the shape of a plurality of channel structures CH1 and CH2.

In an embodiment, the gate stacking structure 120 may be partitioned into a plurality of gate stacking structures 120 by a separation structure 146 in a plan view. The separation structure 146 may extend in a cross direction (for example, a vertical direction) crossing the horizontal conductive layer 110 or in an extension direction (Z-axis direction of the drawing) of the channel structure CH to extend into or penetrate the gate stacking structure 120. In addition, an upper separation region 148 may be formed adjacent to the circuit region 200 in the gate stacking structure 120. In a plan view, the separation structure 146 and/or upper separation region 148 may be provided in plurality, such that the separation structure 146 and/or upper separation region 148 extend in a first direction (Y-axis direction of the drawing) and are spaced apart from each other at a predetermined interval in the second direction (X-axis direction of the drawing) that crosses the first direction.

For example, the separation structure 146 may extend into or penetrate the gate stacking structure 120 and extend up to one surface 120p, and the upper separation region 148 may separate one or a portion of the plurality of gate electrodes 130 from each other. The upper separation region 148 may be disposed between the separation structures 146.

For example, it is illustrated by way of example that the separation structure 146 has an inclined side surface of which a width gradually decreases toward one surface 120p of the horizontal conductive layer 110 or gate stacking structure 120 on a cross-section due to a high aspect ratio, but the embodiments are not limited thereto. A side surface of the separation structure 146 may be vertical to the horizontal conductive layer 110 or may have a bent portion at a connection portion of the plurality of gate stacking structures 120a and 120b.

The separation structure 146 or the upper separation region 148 may be at least partially filled with any of various insulating materials. For example, the separation structure 146 or the upper separation region 148 may include an insulating material such as silicon oxide, silicon nitride, and/or silicon oxynitride. As another example, the separation structure 146 may further include a semiconductor material, a metal material, or the like. In this case, the separation structure 146 may include a spacer layer including an insulating material and a portion formed on the spacer layer and including a semiconductor material, a metal material, or the like. However, the embodiments are not limited thereto, and the structure, shape, material of the separation structure 146 or the upper separation region 148 may be variously modified.

A connection region 104 and a second wiring portion 180 may be provided to connect the gate stacking structure 120 and/or the channel structure CH provided in the cell array region 102 to the circuit region 200 or an external circuit. In addition, a second bonding structure 192 and a second insulation layer 190 may be at a surface of the second wiring portion 180 facing the circuit region 200.

Here, the second wiring portion 180 may include members electrically connecting the gate electrode 130, the channel structure CH, or the like to the circuit region 200 or the external circuit. For example, the second wiring portion 180 may include a bit line 182, a gate contact portion 184, a source contact portion 186, an input/output connection wire 188, and a contact via 180a that is connected to each of them. In addition, the second wiring portion 180 may further include an input/output pad 198. Depending on the embodiments, the second wiring portion 180 may further include a connection wire 190a connected to the bit line 182, the gate contact portion 184, and/or the input/output connection wire 188.

The bit line 182 may be disposed on the cell insulation layer 132 of the gate stacking structure 120 formed in the cell array region 102. The bit line 182 may extend in a second direction (X-axis direction of the drawing) crossing the first direction (Y-axis direction of the drawing) in which the gate electrode 130 extends. The bit line 182 may be electrically connected to the channel structure CH, for example, the channel pad 144 through a contact via 180a, for example, a bit line contact via.

The connection region 104 may be disposed around the cell array region 102, and a portion of the second wiring portion 180 may be disposed therein.

The connection region 104 may include a member for connecting the gate electrode 130 and the circuit region 200. In an embodiment, the gate electrode 130 and the interlayer insulation layer 132m of the plurality of gate stacking structure 120 may be extended in the connection region 104 in the first direction (Y-axis direction of the drawing). For example, a length of the plurality of gate electrodes 130 in a direction away from the cell array region 102 may sequentially extend toward the horizontal conductive layer 110, thereby forming a stair shape. In this case, the plurality of gate electrodes 130 may have a stair shape in one direction or a plurality of directions.

In the drawing, it is illustrated as an example that the gate contact portion 184 is between the gate electrode 130 and the connection wire 190a to connect the gate electrode 130 and the connection wire 190a. However, the embodiments are not limited thereto, and the gate contact portion 184 may be formed by extending into or penetrating the plurality of gate electrodes 130. In this case, the gate contact portion 184 is electrically connected to one connection gate electrode, and may be separated from the other connection gate electrodes by an insulation pattern.

In addition, a source contact portion 186, an input/output pad 198, and an input/output connection wire 188 may be in the connection region 104. For example, the source contact portion 186 may penetrate the cell insulation layer 132 and thus may be electrically connected to the horizontal conductive layer 110. For example, the input/output connection wire 188 may be connected to at least one of the input/output pad 198 and the second bonding structure 192. The input/output pad 198 may be disposed, for example, on the insulation layer 198b at least partially covering at least an outer surface of the horizontal conductive layer 110. Depending on the embodiments, a separate input/output pad electrically connected to the circuit region 200 may be provided. In FIG. 1, it is illustrated by way of example that the insulation layer 198b is disposed between the input/output connection wire 188 and the horizontal conductive layer 110, such that the input/output connection wire 188 and the horizontal conductive layer 110 are not electrically connected. For example, a penetrating portion of the insulation layer 198b may be disposed to extend into or penetrate the horizontal conductive layer 110, and the input/output connection wire 188 may be positioned inside the penetrating portion of the insulation layer 198b. However, the embodiments are not limited thereto. The insulation layer 198b at least partially covering the outer surface of the horizontal conductive layer 110 and the penetrating portion extending into or penetrating the horizontal conductive layer 110 may be formed through different processes or may include different materials. In some embodiments, the horizontal conductive layer 110 might not be formed in a portion where the input/output connection wire 188 is disposed. Numerous other variations are possible in accordance with different embodiments.

The gate contact portion 184, the source contact portion 186, or input/output connection wire 188 may include a conductive material, and, for example, may include tungsten (W), copper (Cu), aluminum (Al), or the like and may further include a diffusion barrier layer. However, the embodiments are not limited to the material of the gate contact portion 184, the source contact portion 186, or the input/output connection wire 188. In FIG. 1, it is illustrated by way of example that the gate contact portion 184 and the source contact portion 186 have inclined side surfaces in each of which a width gradually narrows as it becomes closer to the horizontal conductive layer 110, and the input/output connection wire 188 has an inclined side surface of which a width is widened as it becomes closer the horizontal conductive layer 110. However, the embodiments are not limited thereto. For example, the gate contact portion 184, the source contact portion 186, and/or the input/output connection wire 188 may have a vertical side surface or may have an inclined side surface other than the above-described one. In FIG. 1, it is illustrated by way of example that the gate contact portion 184 and the source contact portion 186 are provided with a bent portion at a boundary portion of the plurality of gate stacking structures 120a and 120b. However, the embodiments are not limited thereto. It is also possible that the gate contact portion 184 or the source contact portion 186 does not have a bent portion at the boundary between the plurality of gate stacking structures 120a and 120b. Numerous other variations are possible in accordance with different embodiments.

One surface of the circuit region 200 adjacent to the cell region 100 is a bonding surface with the cell region 100, and is formed of a first bonding structure 240 and a first insulation layer 250 disposed at the periphery of the first bonding structure 240. One side of the cell region 100, adjacent to the circuit region 200, is a bonding surface with the circuit region 200, and is formed of a second bonding structure 192 and a second insulation layer 190 disposed at the periphery of the second bonding structure 192. The first bonding structure 240 may be disposed on the first wiring portion 230 and electrically connected to the first wiring portion 230, and the second bonding structure 192 may be disposed on the second wiring portion 180 and electrically connected to the second wiring portion 180.

One surface of the cell region 100 and one surface of the circuit region 200 may be bonded to each other by hybrid bonding. In further detail, the first bonding structure 240 of the circuit region 200 and the second bonding structure 192 of the cell region 100 contact each other directly and are bonded to form metal bonding. In addition, the first insulation layer 250 at one surface of the circuit region 200 and the second insulation layer 190 at one surface of the cell region 100 are in direct contact and are bonded to form insulation-layer bonding at the periphery of the first bonding structure 240 and the second bonding structure 192.

For example, the first bonding structure 240 and/or the second bonding structure 192 may be formed of copper, aluminum, tungsten, nickel, gold, tin, manganese, cobalt, titanium, tantalum, ruthenium, or an alloy including the same. For example, the first bonding structure 240 and/or the second bonding structure 192 includes copper in at least the bonding surface, and the metal bonding of the circuit region 200 and the cell region 100 may be a copper-to-copper (copper-to-copper) bonding. In an embodiment, the first insulation layer 250 and the second insulation layer 190 may include the same insulating material in the bonding surface. For example, the first insulation layer 250 and/or the second insulation layer 190 may have a layer including silicon carbonized nitride (SiCN) on at least the bonding surface. However, the embodiments are not limited to the materials of the first bonding structure 240, the second bonding structure 192, the first insulation layer 250, and the second insulation layer 190.

As described, the first bonding structure 240 of the circuit region 200 and the second bonding structure 192 of the cell region 100 may be bonded to provide an electrical connection path between the circuit region 200 and the cell region 100. For example, the bit line 182 connected to the channel structure CH and the gate electrode 130 may be electrically connected to the circuit element 220 of the circuit region 200 by the second wiring portion 180 and the first wiring portion 230.

According to the embodiment, damage to or defects of the channel structure CH may be reduced or prevented by the semiconductor layer 140 including the polycrystalline region 140b having the polycrystalline semiconductor material. In addition, cell current can be increased by the semiconductor layer 140 including the channel region 140a having a crystal structure different from a crystal structure of the polycrystalline region 140b. Accordingly, reliability and performance of the semiconductor device 10 may be improved.

An example of a manufacturing method of the semiconductor device 10 will be described in detail with reference to FIG. 5A to FIG. 5H, together with FIG. 1 to FIG. 3. To the extent that an element is not described in detail below, it may be understood that the element is at least similar to a corresponding element that has been described elsewhere within the present disclosure. Parts that are not described in the above description are described in detail.

FIG. 5A to FIG. 5H are partial cross-sectional views of a semiconductor manufacturing method according to some embodiments. In FIG. 5A to FIG. 5H, a part of the cell array region 102 and a part of the circuit region 200 corresponding to the part are illustrated. Hereinafter, a manufacturing method of the semiconductor device 10 will be mainly described focusing on the horizontal conductive layer 110, the gate stacking structure 120, the channel structure CH, and the separation structure 146 formed in the cell region 100.

As shown in FIG. 5A, the stacking structure 120s is formed on the semiconductor substrate 110s, and a preliminary channel structure CS extending into or penetrating the stacking structure 120s may be formed.

The semiconductor substrate 110s may be a semiconductor substrate including a semiconductor material. For example, the semiconductor substrate 110s may be a semiconductor substrate formed of a semiconductor material, and may be a semiconductor substrate in which a semiconductor layer is formed on a base substrate. For example, the semiconductor substrate 110s may be formed of single crystal silicon or polysilicon, epitaxial silicon, germanium, or silicon-germanium, silicon-on-insulator, and/or germanium-on-insulator.

A stacking structure 120s may be formed by alternately stacking a plurality of sacrificial insulation layers 130s and a plurality of cell insulation layers 132 on the semiconductor substrate 110s. The cell insulation layer 132 may include a bottom insulation layer 132l, an interlayer insulation layer 132m, upper insulation layers 132a and 132b, or the like. Here, the sacrificial insulation layer 130s may be a layer replaced with a gate electrode (refer to 130 of FIG. 5D, hereinafter the same) through a subsequent process. Accordingly, the sacrificial insulation layer 130s may be formed to correspond to a portion where the gate electrode 130 is to be formed.

The sacrificial insulation layer 130s may be formed of a material different from that of the cell insulation layer 132. For example, the cell insulation layer 132 includes silicon oxide, silicon nitride, silicon oxide, and/or a low dielectric constant material, or the like, and the sacrificial insulation layer 130s includes silicon, silicon oxide, silicon carbide, and/or silicon nitride, or the like and may be formed of a material different from that of the cell insulation layer 132.

Subsequently, a penetrating portion extending into or penetrating the stacking structure 120s may be formed to correspond to a portion where a channel structure (refer to CH in FIG. 5D, hereinafter the same) is to be formed, and the preliminary channel structure CS may be formed in the penetrating portion. That is, the gate dielectric layer 150, the preliminary semiconductor layer 140p, and the core insulation layer 142 may be sequentially formed to at least partially fill the penetration portion. In this case, a first blocking layer (refer to 156a of FIG. 2, hereinafter the same) among the gate dielectric layer 150 might not be formed and may be formed later in another process. The preliminary channel structure CS may be in a state without a channel pad (refer to 144 in FIG. 5D).

In this case, a bottom surface of the preliminary channel structure CS may be disposed within the semiconductor substrate 110s. In the preliminary channel structure CS, a portion protruded from one surface 120p of the stacking structure 120s may be a portion that forms the protruded portion CHP of the channel structure CH later. According to this, the protruded portion CHP of the channel structure CH can be stably formed, and a horizontal conductive layer (refer to 110 of FIG. 5E, hereinafter the same) to be formed later can be stably connected to the protruded portion CHP. In other words, process margin can be secured.

In an embodiment, the stacking structure 120s may include a plurality of stacking structures 120d and 120e alternately stacked on the semiconductor substrate 110s, and the preliminary channel structure CS may include a plurality of preliminary channels structure CS1 and CS2 extending into or penetrating the plurality of stacking structures 120d and 120e. However, the embodiments are not limited thereto.

In an embodiment, the preliminary semiconductor layer 140p may be formed of an amorphous semiconductor layer having an amorphous structure. For example, the preliminary semiconductor layer 140p may be formed of an amorphous silicon layer. According to this, the preliminary semiconductor layer 140p can be easily formed by a process such as deposition.

Here, the preliminary semiconductor layer 140p may include a first region 140g at least partially filling at least the protruded portion CHP, and a second region 140h at an inner portion (refer to CH1 of FIG. 2, hereinafter the same). The description of the polycrystalline region 140b may be applied as it is to the shape and size of the first region 140g. The description of the channel region 140a may be applied as it is to the shape and size of the second region 140h. For example, the first region 140g may have a stopper shape, a plug shape, or a truncated circular cone shape at least partially filling an end portion of the preliminary channel structure CS or the protruded portion CHP. The second region 140h may have a layered shape bordering or surrounding an outer surface of a core insulation layer 142 on the gate dielectric layer 150 formed on the side surface of the preliminary channel structure CH.

The first region 140g is a portion to form a polycrystalline region (refer to 140b in FIG. 5C) after the crystallization process, and the second region 140h is a portion to form a channel region (refer to 140a in FIG. 5C) after the crystallization process.

In an embodiment, the first region 140g and the second region 140h having the above-described shapes may be formed by adjusting a size of the channel structure CH or the penetration portion, a thickness of the preliminary semiconductor layer 140p, or the like. For example, a diameter or a width of the channel structure CH or the penetration portion, a diameter or a width of the bottom surface (refer to 140t of FIG. 3) of the preliminary semiconductor layer 140p at the protruded portion CHP, a height of the protruded portion CHP, a thickness of the preliminary semiconductor layer 140p, or the like may be adjusted such that the inner surfaces of the preliminary semiconductor layer 140p are in contact with each other in the protruded portion CHP and the inner surfaces of the preliminary semiconductor layer 140p are not in contact with each other in the inner portion CH1.

In an embodiment, the preliminary semiconductor layer 140p is formed after the gate dielectric layer 150 is formed, and therefore, it may not be necessary to perform a process of removing the gate dielectric layer 150 formed on the preliminary semiconductor layer 140p (e.g., the first region 140g). Accordingly, it can be generally easily applied even in the case of a large number of gate electrodes 130.

Subsequently, as shown in FIG. 5B, a metal layer 140m may be formed on the upper surface of the preliminary channel structure CS or the other surface 120q of the stacking structure 120s. Here, the metal layer 140m may be a metal layer including a crystallization-inducing metal, or, for example, may be a single metal layer including a single crystallization-inducing metal. In an embodiment, the metal layer 140m may include nickel, cobalt, palladium, copper, or the like. The metal layer 140m may be formed by any of various methods, and it can be formed by for example, deposition or the like.

However, the embodiments are not limited thereto. Therefore, the metal layer 140m may include a material other than metal, and the metal layer 140m may be formed by a process other than deposition.

Subsequently, as shown in FIG. 5C, the semiconductor layer 140 having the channel region 140a and the polycrystalline region 140b may be formed by performing a heat treatment process for crystallizing the preliminary semiconductor layer (refer to 140p in FIG. 5B, hereinafter the same).

In an embodiment, a heat treatment process is performed to form a metal-semiconductor compound including the metal included in the metal layer (refer to 140m in FIG. 5B, hereinafter the same), and a process of removing the metal layer 140m may be performed, and then, a heat treatment process for crystallization may be performed.

In this case, the heat treatment process for forming the metal-semiconductor compound may be performed at a lower temperature (e.g., less than 500 degrees Celsius, for example, 300 degrees Celsius to 400 degrees Celsius) than the heat treatment process for crystallization. In the annealing process, the crystallization-inducing metal included in the metal layer 140m is diffused into the second region 140h and may be chemically combined with the semiconductor material provided in the second region 140h. Accordingly, the compound portion including the metal-semiconductor compound (e.g., metal silicide) in which the crystallization-inducing metal and the semiconductor material (e.g., silicon) are chemically bonded may be formed in the second region 140h. For example, the compound portion may be formed in a portion of the second region 140h (e.g., an upper portion of the second region 140h).

The process of removing the metal layer 140m may be performed by any of various processes (e.g., etching process, etc.) that can remove the metal layer 140m.

The heat treatment process for crystallization may be performed at a higher heat treatment temperature (e.g., 500 degrees Celsius or higher, in further detail, 500 degrees Celsius to 700 degrees Celsius) than the heat treatment process for forming the metal-semiconductor compound. In this case, the heat treatment process for crystallization may be performed at a heat treatment temperature at which both solid phase crystallization and metal-induced crystallization are possible. That is, the polycrystalline region 140b and the channel region 140a having different crystal structures may be formed in one process.

In this case, the first region 140g having a relatively large size or thickness may be crystallized by a solid phase crystallization process to form a polycrystalline region 140b having a polycrystalline structure. The second region 140h having a relatively small size or thickness may be crystallized by a metal-induced crystallization process to form a channel region 140a having a single crystal structure or a quasi-single crystal structure. In this case, the crystallization-inducing metal does not move to the polycrystalline region 140b and remains in a portion adjacent to the polycrystalline region 140b. Accordingly, an interface portion 140f may be formed adjacent to the polycrystalline region 140b. The interface portion 140f may include a metal-semiconductor compound where the semiconductor material included in the preliminary semiconductor layer 140p or the semiconductor layer 140 and the crystallization-inducing metal are chemically bonded to each other.

Accordingly, a semiconductor layer 140 including the channel region 140a, having the channel portion 140e and the interface portion 140f, and a polycrystalline region 140b may be formed.

However, the above crystallization process is presented as an example, but the embodiments are not limited thereto. For example, the process of removing the metal layer 140m may be performed after the metal-induced crystallization process, or the heat treatment process for forming the metal-semiconductor compound (for example, the annealing process) and a metal-induced crystallization process may be performed as a continuous process or as the same process. Numerous other variations are possible.

As in the embodiment described above, the heat treatment process for crystallization may be performed before forming the channel pad 144. A heat treatment process is included in the process of forming the channel pad 144. If the preliminary semiconductor layer 140p is crystallized by the heat treatment process performed in the process of forming the channel pad 144, it may be difficult to form the semiconductor layer 140 having desired properties. However, the embodiments are not limited thereto.

Subsequently, as shown in FIG. 5D, a channel structure CH may be formed by forming the channel pad 144 connected to the semiconductor layer 140. In addition, a sacrificial insulation layer (refer to 130s in FIG. 5C, hereinafter the same) may be replaced with a gate electrode 130, and a separation structure 146 may be formed.

First, an opening may be formed in a region corresponding to the separation structure 146 to pass through the stacking structure 120s. The sacrificial insulation layer 130s may be selectively removed by an etching process (e.g., wet etching process) through the opening. In addition, the gate electrode 130 may be formed by at least partially filling a conductive material in a portion from which the sacrificial insulation layer 130s is removed. As a result, the region where the sacrificial insulation layer 130s is disposed may be replaced with the gate electrode 130. In this case, a process of forming the first blocking layer 156a may be further performed before the process of at least partially filling the conductive material that forms the gate electrode 130. Subsequently, an insulating material or the like may be at least partially filled in the opening to form a separation structure 146.

According to the embodiment, an upper separation region (refer to 148 of FIG. 1, hereinafter the same) may be further formed in a part of the second stacking structure 120e. The upper separation region 148 may be formed by forming an upper separation opening by an etching process using a mask layer and depositing an insulating material in the upper separation opening. The process of forming the upper separation region 148 may be performed before or after the metal-induced crystallization process, before or after the forming process of the opening or separation structure 146, or the like. That is, the order of processes forming the upper separation region 148 is not limited. In some embodiments, the upper separation region 148 might not be formed.

Then, a second wiring portion 180 connected to the channel structure CH, a second bonding structure 192, a second insulation layer 190, or the like may be formed to form a preliminary cell region 100a. The preliminary cell region 100a may mean a cell region before the formation of the horizontal conductive layer 110 is completed.

Subsequently, as shown in FIG. 5E, the preliminary cell region 100a may be bonded on the circuit region 200. For example, an upper surface (the upper surface in FIG. 5D or the bottom surface in FIG. 5E) of the preliminary cell region 100a may be bonded on the circuit region 200.

In a bonding process between the circuit region 200 and the preliminary cell region 100a, the preliminary cell region 100a may be bonded on the circuit region 200 in a vertically inverted state. The circuit region 200 and the preliminary cell region 100a are bonded by hybrid bonding including metal bonding of the first bonding structure 240 and the second bonding structure 192 and insulation-layer bonding of the first insulation layer 250 and the second insulation layer 190. For example, the hybrid bonding may be performed by performing an annealing process while the circuit region 200 and the preliminary cell region 100a are in contact with each other.

Subsequently, as shown in FIG. 5F, the semiconductor substrate (refer to 110s in FIG. 5E, hereinafter the same) may be removed. As a process for removing the semiconductor substrate 110s, at least one of an etching process (wet etching process, dry etching process, etc.), a chemical mechanical polishing process, and a stripping process may be applied.

For example, the semiconductor substrate 110s may be removed by performing a wet etching process using an etching material that can etch the semiconductor substrate 110s after performing a chemical mechanical polishing process. The etching material of the semiconductor substrate 110s may be a material that has an etching selectivity relative to the cell insulation layer 132 (e.g., a bottom insulation layer 132l), the gate dielectric layer 150, or the like, such that the etching material is less effective at etching the cell insulation layer 132, gate dielectric layer 150, etc. than it is at etching the semiconductor substrate 110s or may be a material with a low etching speed of the cell insulation layer 132 (e.g., bottom insulation layer 132l), the gate dielectric layer 150, or the like.

Subsequently, as shown in FIG. 5G, the gate dielectric layer 150 disposed on the protruded portion CHP of the channel structure CH may be removed. A process of removing the gate dielectric layer 150 may be performed by an etching process (e.g., wet etching process) using an etching material that can etch the gate dielectric layer 150.

In this case, the etching material for etching the gate dielectric layer 150 may be a material that has an etching selectivity relative to the polycrystalline semiconductor material (e.g., polysilicon), such that the etching material is less effective at etching the polycrystalline semiconductor material that it is at etching the gate dielectric layer 150 or be a material in which the etching speed of the polycrystalline semiconductor material (e.g., polysilicon) is relatively low. For example, the etching material of the gate dielectric layer 150 may be a fluorine-based material, but the embodiments are not limited thereto.

In the embodiment, the polycrystalline region 140b including a polycrystalline semiconductor material (e.g., polysilicon) is disposed at a lower portion of the gate dielectric layer 150 at the protruded portion CHP of the channel structure CH. Therefore, in the process of removing the gate dielectric layer 150, the gate dielectric layer 150 may be selectively removed without damaging or etching the polycrystalline region 140b.

That is, in the process of removing the gate dielectric layer 150, the polycrystalline region 140b may protect the channel structure CH. For example, the polycrystalline region 140b may inhibit or prevent the etching material from removing the insulating material included in the gate dielectric layer 150 and reaching the core insulation layer 142 that is formed of the insulating material. Accordingly, damage or removal of the core insulation layer 142 may be reduced or prevented in the process of removing the gate dielectric layer 150.

For reference, conventionally, a part containing metal silicide is positioned at a protruded portion of a channel structure. According to this, in the process of removing the gate dielectric layer, the part containing the metal silicide is removed, the core insulation layer is exposed, and a defect in that the core insulation layer is also removed may occur. When such a defect occurs, performance and reliability of the semiconductor device may deteriorate.

Subsequently, as shown in FIG. 5H, the horizontal conductive layer 110 may be formed to at least partially cover the protruded portions CHP of the plurality of channel structures CH and one surface 120p of the gate stacking structure 120 exposed between the protruded portions CHP.

A process of forming the horizontal conductive layer 110 may be performed using deposition or the like. For deposition, chemical vapor deposition, atomic layer deposition, or the like may be used. However, the embodiments are not limited thereto, and the horizontal conductive layer 110 may be formed by any of various processes. For example, after forming an amorphous silicon layer including a dopant, a heat treatment process for crystallization and/or activation may be performed to form the horizontal conductive layer 110. However, the embodiments are not limited thereto.

After forming the horizontal conductive layer 110, a process of forming an insulation layer 198b on an outer surface of the horizontal conductive layer 110 may be further performed.

According to the embodiment, in the heat treatment process for crystallization, the first region 140g of the preliminary semiconductor layer 140p is crystallized into the polycrystalline region 140b having a polycrystalline structure, and the second region 140h of the preliminary semiconductor layer 140p is crystallized into channel region 140a having a single crystal structure or quasi-single crystal structure. That is, the polycrystalline region 140b and the channel region 140a having different crystal structures may be formed in the same heat treatment process by using a difference in shape between the first region 140g and the second region 140h. Accordingly, the channel region 140a has a single crystal structure or a quasi-single crystal structure, and the polycrystalline region 140b might not include a metal or metal-semiconductor compound. Undesired damage or removal of the semiconductor layer 140 and/or the core insulation layer 142 at the protruded portion CHP of the channel structure CH can be reduced or prevented by the polycrystalline region 140b. That is, the semiconductor device 10 having improved reliability and performance can be formed by a process of reasonable complexity.

An example of an electronic system including the semiconductor device as described above will be described in detail.

FIG. 6 schematically illustrates an electronic system including a semiconductor device according to some embodiments.

Referring to FIG. 6, an electronic system 1000 according to an embodiment may include a semiconductor device 1100 and a controller 1200 that is electrically connected with the semiconductor device 1100. The electronic system 1000 may be a storage device including one or a plurality of semiconductor devices 1100 or an electronic device including the storage device. For example, the electronic system 1000 may be a solid-state drive (SSD) device including one or a plurality of semiconductor devices 1100, a medical device, or a communication device.

The semiconductor device 1100 may be a non-volatile memory device, and, for example, may be a NAND flash memory device described with reference to FIG. 1 to FIG. 4 and FIG. 5A to FIG. 5H. The semiconductor device 1100 may include a first structure 1100F and a second structure 1100S on the first structure 1100F. In an embodiment, the first structure 1100F may be disposed next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a word line WL, a first upper line UL1 and a second gate upper line UL1 and UL2, first gate lower line LL1 and a second gate lower line and LL2, and a memory cell string CSTR between the bit line BL and the common source line CSL.

In the second structure 1100S, each memory cell string CSTR may include lower transistor LT1 and LT2 adjacent to the common source line CSL, upper transistors UT1 and UT2 adjacent to the bit line BL, and a plurality of memory cell transistors MCT between the lower transistors LT1 and LT2 and the upper transistors UT1 and UT2. The number of lower transistors LT1 and LT2 and the number of upper transistors UT1 and UT2 may be variously modified depending on embodiments.

In an embodiment, the lower transistors LT1 and LT2 may include ground selection transistors, and the upper transistors UT1 and UT2 may include string selection transistors. The first gate lower line LL1 and the second gate lower line LL2 may be gate electrodes of the lower transistors LT1 and LT2, respectively. The word line WL may be a gate electrode of the memory cell transistor MCT, and the gate upper lines UL1 and UL2 may be gate electrodes of the upper transistors UT1 and UT2, respectively.

The common source line CSL, the first and second gate lower lines LL1 and LL2, the word line WL, and the first and second gate upper lines UL1 and UL2 may be electrically connected with a decoder circuit 1110 through a first connection wire 1115 extending to the second structure 1100S from the first structure 1100F. The bit line BL may be electrically connected with a page buffer 1120 through a second connection wire 1125 extending to the second structure 1100S from the first structure 1100F.

In the first structure 1100F, the decoder circuit 1110 and the page buffer 1120 may perform a control operation for at least one memory cell among the plurality of memory cell transistors MCT. The decoder circuit 1110 and the page buffer 1120 may be controlled by a logic circuit 1130. The semiconductor device 1100 may communicate with the controller 1200 through an input/output pad 1101 that is electrically connected with the logic circuit 1130. The input/output pad 1101 may be electrically connected with the logic circuit 1130 through an input/output connection wire 1135 extending to the second structure 1100S from the first structure 1100F.

The controller 1200 may include a processor 1210, a NAND controller 1220, and a host interface 1230. Depending on embodiments, the electronic system 1000 may include a plurality of semiconductor devices 1100, and in this case, the controller 1200 may control the plurality of semiconductor devices 1100.

The processor 1210 may control the overall operation of the electronic system 1000 including the controller 1200. The processor 1210 may operate according to execution of predetermined firmware, and may access the semiconductor device 1100 by controlling the NAND controller 1220. The NAND controller 1220 may include a NAND interface 1221 that processes communication with the semiconductor device 1100. A control command for controlling the semiconductor device 1100, data to be recorded in the memory cell transistor MCT of the semiconductor device 1100, data to be read from the semiconductor device 1100, or the like may be transmitted through the NAND interface 1221. The host interface 1230 may provide a communication function between the electronic system 1000 and an external host. When receiving a control command from the external host through the host interface 1230, the processor 1210 may control the semiconductor device 1100 responding to the control command.

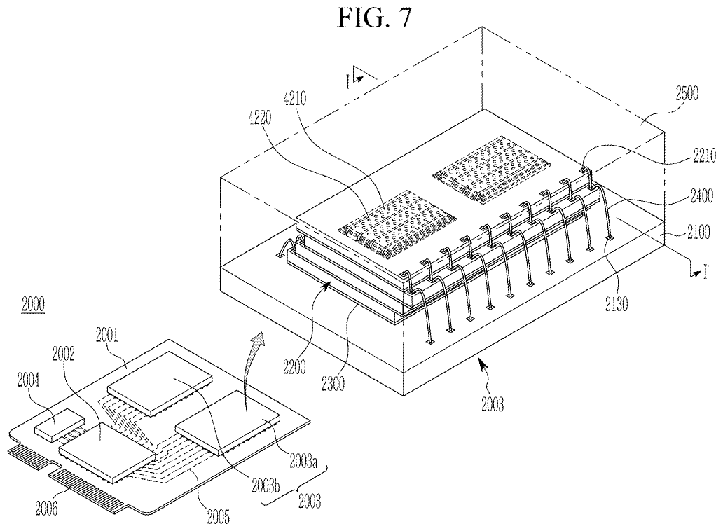

FIG. 7 schematically illustrates an electronic system including a semiconductor device according to some embodiments.

Referring to FIG. 7, an electronic system 2000 according to an embodiment may include a main substrate 2001, a controller 2002 mounted on the main substrate 2001, one or more semiconductor packages 2003, and a DRAM 2004. The semiconductor package 2003 and the DRAM 2004 may be connected with the controller 2002 by a wiring pattern 2005 formed in the main substrate 2001.

The main substrate 2001 may include a connector 2006 including a plurality of pins combined with the external host. The number and disposition of the plurality of pins in the connector 2006 may vary depending on a communication interface between the electronic system 2000 and the external host. In an embodiment, the electronic system 2000 may communicate with the external host through one of interfaces such as a universal serial bus (USB), a peripheral component interface (PCI)-express, a serial advanced technology attachment (ADTA), and/or M-Phy for a universal flash storage (UFS), or the like. In an embodiment, the electronic system 2000 may operate by power supplied from the external host through the connector 2006. The electronic system 2000 may further include a power management integrated circuit (PMIC) that distributes power supplied from the external host to the controller 2002 and the semiconductor package 2003.

The controller 2002 may record data to the semiconductor package 2003 or read data from the semiconductor package 2003, and may improve operation speed of the electronic system 2000.

The DRAM 2004 may be a buffer memory for mitigating a speed difference between the semiconductor package 2003, which is a data storage space, the external host. The DRAM 2004 included in the electronic system 2000 may operate as one of cache memory, and may provide a space for temporarily storing data in the control operation for the semiconductor package 2003. When the DRAM 2004 is included in the electronic system 2000, the controller 2002 may further include a DRAM controller for controlling the DRAM 2004 in addition to the NAND controller for controlling the semiconductor package 2003.

The semiconductor package 2003 may include a first semiconductor package 2003a and a second semiconductor package 2003b that are spaced apart from each other. The first semiconductor package 2003a and the second semiconductor package 2003b may be respective semiconductor packages including a plurality of semiconductor chips 2200. Each of the first semiconductor package 2003a and the second semiconductor package 2003b may include a package substrate 2100, a semiconductor chip 2200 on the package substrate 2100, an adhesive layer 2300 disposed on a bottom surface of each of the semiconductor chips 2200, a connection structure 2400 that electrically connects the semiconductor chip 2200 and the package substrate 2100, and a molding layer 2500 that at least partially covers the semiconductor chip 2200 and the connection structure 2400 on the package substrate 2100.

The package substrate 2100 may be a printed circuit board including a package upper pad 2130. Each semiconductor chip 2200 may include an input/output pad 2210. The input/output pad 2210 may correspond to the input/output pad 1101 of FIG. 6. Each semiconductor chip 2200 may include a gate stacking structure 3210 and a channel structure 3220. The semiconductor chip 2200 may include the semiconductor device described with reference to FIG. 1 to FIG. 4 and FIG. 5A to FIG. 5H.

In an embodiment, the connection structure 2400 may be a bonding wire that electrically connects the input/output pad 2210 and the package upper pad 2130. Thus, in each of the first semiconductor package 2003a and the second semiconductor package 2003b, the semiconductor chips 2200 may be electrically connected with each other through a bonding wire method, and may be electrically connected with the package upper pad 2130 of the package substrate 2100. Depending on embodiments, in each of the first semiconductor package 2003a and the second semiconductor package 2003b, the semiconductor chips 2200 are electrically connected to each other by a connection structure including a through electrode (Through Silicon Via, TSV) instead of the connection structure 2400 of the bonding wire type.

In an embodiment, the controller 2002 and the semiconductor chip 2200 may be included in a single package. For example, the controller 2002 and the semiconductor chip 2200 are mounted on a separate interposer substrate that is different from the main substrate 2001, and the controller 2002 and the semiconductor chip 2200 may be connected with each other by a wire formed in the interposer substrate.

FIG. 8 is a schematic cross-sectional view of a semiconductor package according to an embodiment. FIG. 8 illustrates an embodiment of the semiconductor package 2003, and conceptually illustrates a region cut along the line I-I′ of the semiconductor package 2003 of FIG. 7.

Referring to FIG. 8, in a semiconductor package 2003, a package substrate 2100 may be a printed circuit board. The package substrate 2100 may include a package substrate body portion 2120, a package upper pad 2130 disposed on an upper surface of the package substrate body portion 2120, a lower pad 2125 disposed on a bottom surface of the package substrate body portion 2120 or exposed through the bottom surface, and an internal wire 2135 that electrically connects the upper pad 2130 and the lower pad 2125 in the package substrate body portion 2120. The upper pad 2130 may be electrically connected with the connection structure 2400. The lower pad 2125 may be connected to the wiring pattern 2005 of the main substrate 2010 of the electronic system 2000 as shown in FIG. 7 through a conductive connection portion 2800.

In the semiconductor package 2003, each semiconductor chip 2200 may include a semiconductor substrate 4010, a first structure 4100 on the semiconductor substrate 4010, and a second structure 4200 bonded to the first structure 4100 by a wafer bonding method.

The first structure 4100 may include a peripheral circuit region including a peripheral wire 4110 and first bonding structure 4150. The second structure 4200 may include a common source line 4205, a gate stacking structure 4210 between the common source line 4205 and the first structure 4100, a channel structure 4220 and a separation structure 4230 that extend into or penetrate the gate stacking structure 4210, a second bonding structure that is electrically connected with word lines (refer to WL in FIG. 6, hereinafter the same) of the channel structure 4220 and the gate stacking structure 4210. For example, the second bonding structure 4250 may be electrically connected with the channel structure 4220 and the word line WL through a bit line 4240 electrically connected with the channel structure 4220 and a gate connection wire electrically connected with the word line WL. The first bonding structure 4150 of the first structure 4100 and the second bonding structure 4250 of the second structure 4200 may be bonded to each other while being in contact with each other. A bonded portion of the first bonding structure 4150 and the second bonding structure 4250 may be formed of, for example, copper (Cu).

In the semiconductor chip 2200 or the semiconductor device according to an embodiment, damage to or defects of the channel structure may be reduced or prevented by a semiconductor layer including a polycrystalline region, and cell current can be increased by the semiconductor layer including a channel region. Accordingly, reliability and performance of the semiconductor chip 2200 or the semiconductor device can be improved.

Each of the semiconductor chips 2200 may further include an input/output pad 2210 and an input/output connection wire 4265 under the input/output pad 2210. The input/output connection wire 4265 may be electrically connected to a part of the second bonding structure 4250.

In an embodiment, a plurality of semiconductor chips 2200 in the semiconductor package 2003 may be electrically connected to each other by the connection structure 2400 in the form of a bonding wire. As another example, the plurality of semiconductor chip 2200 or a plurality of parts forming the same may be electrically connected by a connection structure including a through electrode.

Embodiments have been described in detail above, but the scope of the present disclosure is not limited thereto. Numerous variations and improvements made by a person of an ordinary skill in the art using the basic concept of the present disclosure as defined in the following claims may also fall within the scope of the present disclosure.

What is claimed is:

1. A semiconductor device comprising:
a gate stacking structure that includes a plurality of gate electrodes and a plurality of insulation layers that are alternately stacked;
a channel structure that includes an inner portion extending into the gate stacking structure and a protruded portion that protrudes from one surface of the gate stacking structure; and
a horizontal conductive layer that is connected to the protruded portion of the channel structure,
wherein the channel structure comprises a semiconductor layer including a polycrystalline region in at least the protruded portion and including a polycrystalline semiconductor material and in a channel region positioned in the inner portion and having a crystal structure that is different from a crystal structure of the polycrystalline region.

2. The semiconductor device of claim 1, wherein the channel region has a single crystal structure or a quasi-single crystal structure.

3. The semiconductor device of claim 1, wherein the channel region comprises a channel portion and an interface portion between the channel portion and the polycrystalline region, and
the channel portion and the interface portion comprise different materials.

4. The semiconductor device of claim 3, wherein the interface portion includes a metal,
wherein the channel portion is free of the metal or includes the metal in a lower content than the interface portion, and
wherein the polycrystalline region is free of the metal or includes the metal in a lower content than the interface portion.

5. The semiconductor device of claim 3, wherein the channel portion includes the same material as the polycrystalline region, and
wherein the interface portion includes a metal-semiconductor compound that includes the polycrystalline semiconductor material included in the channel portion and a metal.

6. The semiconductor device of claim 3, further comprising:
a bottom insulation layer between a gate electrode that is adjacent to the one surface of the gate stacking structure among the plurality of gate electrodes and the horizontal conductive layer, and
wherein the interface portion is at a location where the bottom insulation layer is in an extension direction of the channel structure.

7. The semiconductor device of claim 1, wherein the channel region comprises a channel portion and an interface portion between the channel portion and the polycrystalline region,
wherein the polycrystalline region comprises polysilicon,
wherein the channel portion comprises single crystal or quasi-crystal silicon, and
wherein the interface portion comprises single crystal or quasi-crystal metal silicide.

8. The semiconductor device of claim 1, wherein a height of the polycrystalline region in an extension direction of the channel structure is greater than a thickness of the channel region in a direction that crosses a side surface of the channel structure.

9. The semiconductor device of claim 8, wherein a ratio of the height of the polycrystalline region to the thickness of the channel region is two or more.

10. The semiconductor device of claim 1, wherein a height of the polycrystalline region in an extension direction of the channel structure is equal to or greater than a diameter or a width of a bottom surface of the polycrystalline region in a direction crossing the extension direction.

11. The semiconductor device of claim 10, wherein a ratio of the height of the polycrystalline region to the diameter or the width of the bottom surface of the polycrystalline region is 1.5 or more.

12. The semiconductor device of claim 1, wherein a height of the polycrystalline region in an extension direction of the channel structure is equal to or greater than a height of the protruded portion in the extension direction of the channel structure.

13. The semiconductor device of claim 1, wherein the channel region comprises a channel portion and an interface portion between the channel portion and the polycrystalline region and including a metal, and
wherein a height of the interface portion in an extension direction of the channel structure is less than a height of the polycrystalline region in the extension direction of the channel structure.

14. The semiconductor device of claim 1, further comprising a core insulation layer inside the channel region and on the polycrystalline region.

15. The semiconductor device of claim 1, wherein the channel structure further comprises a gate dielectric layer that at least partially surrounds the semiconductor layer in the inner portion, and a core insulation layer inside the channel region and on the polycrystalline region, and
wherein a boundary portion between the polycrystalline region and the channel region or a bottom surface of the core insulation layer is on a same plane with a bottom surface of the gate dielectric layer adjacent to the protruded portion or is at an inside of the gate stacking structure or the bottom surface of the gate dielectric layer.

16. The semiconductor device of claim 1, further comprising a circuit region including a peripheral circuit structure,
wherein a cell region including the gate stacking structure, the channel structure, and the horizontal conductive layer is bonded on the circuit region, and
the horizontal conductive layer includes a substrate that is on side and bottom surfaces of the polycrystalline region at the protruded portion.

17. An electronic system comprising:
a main substrate;
a semiconductor device on the main substrate; and
a controller that is electrically connected with the semiconductor device on the main substrate,
wherein the semiconductor device comprises:
a gate stacking structure including a plurality of gate electrodes and a plurality of insulation layers that are alternately stacked;
a channel structure including an inner portion extending into the gate stacking structure, and a protruded portion that protrudes from one surface of the gate stacking structure; and
a horizontal conductive layer connected to the protruded portion of the channel structure,
wherein the channel structure comprises a polycrystalline region in the protruded portion and including a polycrystalline semiconductor material, and in a channel region positioned in the inner portion and having a crystal structure different from a crystal structure of the polycrystalline region.

18. A manufacturing method of a semiconductor device, comprising:
forming a stacking structure including a plurality of sacrificial insulation layers and a plurality of insulation layers that are alternately stacked on a substrate;
forming a preliminary channel structure by forming a penetration portion extending into the stacking structure, the preliminary channel structure including a preliminary semiconductor layer including an amorphous semiconductor material in the penetration portion;
forming a semiconductor layer by performing a heat treatment process for crystallization of the preliminary semiconductor layer; and
forming a plurality of gate electrodes by substituting the plurality of sacrificial insulation layers with the plurality of gate electrodes,
wherein, in the forming of the semiconductor layer, a first region of the preliminary semiconductor layer is crystallized to have a polycrystalline structure, and a second region of the preliminary semiconductor layer is crystallized to have a single crystal structure or a quasi-single crystal structure.

19. The manufacturing method of the semiconductor device of claim 18, further comprising:
forming a metal layer including a metal on the preliminary channel structure between the forming of the preliminary channel structure and the forming of the semiconductor layer,
wherein, in the forming of the semiconductor layer, the first region is crystallized to have the polycrystalline structure by a solid phase crystallization process, and the second region is crystallized to have the single crystal structure or the quasi-single crystal structure by a metal-induced crystallization process using the metal.

20. The manufacturing method of the semiconductor device of claim 18, wherein, in the forming of the preliminary channel structure, the preliminary channel structure includes an inner portion extending into the stacking structure and a protruded portion that protrudes from one surface of the stacking structure, and
wherein the first region of the preliminary semiconductor layer is in at least a portion of the protruded portion, and the second region of the preliminary semiconductor layer is positioned in the inner portion and has a layered shape, such that a core insulation layer is inside the second region.
